(19) United States
(12) Patent Application Publication
(10) Pub. No.: US 2025/0393191 A1
(43) Pub. Date: Dec. 25, 2025

(54) SEMICONDUCTOR MEMORY DEVICE

(71) Applicant: Samsung Electronics Co., Ltd., Suwon-si (KR)

(72) Inventors: Kyul KO, Suwon-si (KR); Dong Gyu HEO, Suwon-si (KR); Jun Soo KIM, Suwon-si (KR); Dae Hyun MOON, Suwon-si (KR); Sung Ho JANG, Suwon-si (KR)

(73) Assignee: Samsung Electronics Co., Ltd., Suwon-si (KR)

(21) Appl. No.: 19/034,732

(22) Filed: Jan. 23, 2025

(30) Foreign Application Priority Data
Jun. 24, 2024 (KR) 10-2024-0081752

(51) Int. Cl. H10B 12/00; H01L 23/00; H01L 25/065; H01L 25/18; H10B 80/00

(52) U.S. Cl. CPC H10B 12/315; H01L 24/08; H01L 25/0657; H01L 25/18; H10B 12/05; H10B 12/056; H10B 12/34; H10B 12/50; H10B 80/00; H01L 2224/08145; H01L 2924/1431; H01L 2924/1436

(57) ABSTRACT

A semiconductor memory device includes a channel region, a word line extending in a first direction, a gate insulating film being between the channel region and the word line and including silicon oxide, a first gate metal oxide film being between the gate insulating film and the word line, the first gate metal oxide film including first metal oxide, and a capping gate metal oxide film on an upper face of the word line and including second metal oxide, wherein the first gate metal oxide film includes a doped impurity element, and a concentration of the doped impurity element in the first gate metal oxide film is greater than a concentration of the doped impurity element in the capping gate metal oxide film.

### CROSS-REFERENCE TO RELATED APPLICATION

This application claims priority from Korean Patent Application No. 10-2024-0081752 filed on Jun. 24, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to semiconductor memory devices.

### 2. Description of the Related Art

It is desired to increase the degree of integration of a semiconductor memory device to satisfy higher performance and lower price desired by consumers. Because the degree of integration is an important factor in determining the price of a product in the case of the semiconductor memory device, an increased degree of integration is particularly required.

In the case of a two-dimensional or planar semiconductor memory device, the degree of integration is mainly determined by an area occupied by unit memory cells, and is therefore greatly affected by the level of fine pattern forming technique. However, because ultra-expensive apparatuses are required to miniaturize the pattern, the degree of integration of the two-dimensional semiconductor memory device is increasing, but is still limited. Accordingly, semiconductor memory devices including vertical channel transistors with channels extending in a vertical direction have been proposed.

### SUMMARY

Some example embodiments of the present disclosure provide semiconductor memory devices having improved degree of integration and electrical characteristics.

However, example embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor memory device includes a channel region, a word line extending in a first direction, a gate insulating film being between the channel region and the word line, the gate insulating film including silicon oxide, a first gate metal oxide film being between the gate insulating film and the word line, the first gate metal oxide film including first metal oxide, and a capping gate metal oxide film on an upper face of the word line, the capping gate metal oxide film including second metal oxide, wherein the first gate metal oxide film includes a doped impurity element, and a concentration of the doped impurity element in the first gate metal oxide film is greater than a concentration of the doped impurity element in the capping gate metal oxide film.

According to an example embodiment of the present disclosure, a semiconductor memory device includes a bit line extending in a first direction on a substrate, an active pattern on the bit line, the active pattern including a first side wall and a second side wall that are opposite to each other in the first direction, the active pattern including a first surface and a second surface that are opposite to each other in a vertical direction, the first surface of the active pattern being connected to the bit line, a word line on the first side wall of the active pattern, the word line extending in a second direction, the word line including a first surface and a second surface that are opposite to each other in the vertical direction, a gate insulating film extending along the first side wall of the active pattern, the gate insulating film being in contact with the active pattern, the gate insulating film including silicon oxide, a gate metal oxide film between the gate insulating film and the word line, the gate metal oxide film including first metal oxide that is oxide of a metal element included in the word line, a capping gate metal oxide film on the first surface of the word line, the capping gate metal oxide film including the first metal oxide, a back gate electrode on the second side wall of the active pattern, the back gate electrode extending in the second direction, and a data storage pattern on the active pattern, the data storage pattern connected to the second surface of the active pattern, wherein the gate metal oxide film includes a doped first impurity element, and a thickness of the capping gate metal oxide film is greater than a thickness of the gate metal oxide film.

According to an example embodiment of the present disclosure, a semiconductor memory device includes a peri-gate structure on a substrate, a bit line extending in a first direction on the peri-gate structure, a shielding conductive pattern on the peri-gate structure, the shielding conductive pattern including a plurality of shielding conductive line patterns extending in the first direction to be adjacent to the bit line, a first word line on the bit line and the shielding conductive pattern, the first word line extending in a second direction, the first word line including a first surface and a second surface that are opposite to each other in a vertical direction, a second word line on the bit line and the shielding conductive pattern, the second word line extending in the second direction, the second word line being spaced apart from the first word line in the first direction, a back gate electrode between the first word line and the second word line, the back gate electrode extending in the second direction, a first active pattern on the bit line, the first active pattern being between the first word line and the back gate electrode, a second active pattern on the bit line, the second active pattern being between the second word line and the back gate electrode, a first gate metal oxide film between the first word line and the first active pattern, the first gate metal oxide film including first metal oxide, a second gate metal oxide film between the second word line and the second active pattern, the second gate metal oxide film including the first metal oxide, a back gate metal oxide film being between the back gate electrode and the first active pattern and being between the back gate electrode and the second active pattern, and the back gate metal oxide film including second metal oxide, and a data storage pattern connected to a respective one of the first active pattern and the second active pattern, wherein each of the first gate metal oxide film and the second gate metal oxide film includes a first impurity element, the first word line and the second word line include a metal element, the first metal oxide is oxide of the metal element, and the first impurity element includes at least one of niobium (Nb), tantalum (Ta), vanadium (V), zirconium (Zr), aluminum (Al), molybdenum (Mo), cobalt (Co), phosphorus (P), nitrogen (N), or arsenic (As).

It should be noted that the effects and advantages of the present disclosure are not limited to those described above, and other effects and advantages of the present disclosure will be apparent from the following description.

### BRIEF DESCRIPTION OF DRAWINGS

The above and other aspects and features of the present disclosure will become more apparent by describing in detail illustrative example embodiments thereof with reference to the attached drawings, in which:

FIG. 1 is a layout diagram for explaining a semiconductor memory device according to an example embodiment.

FIG. 2 is a cross-sectional view taken along A-A and B-B of FIG. 1.

FIG. 3 is a cross-sectional view taken along C-C and D-D of FIG. 1.

FIG. 4 is an enlarged view of a portion P of FIG. 2.

FIGS. 5 to 7 are diagrams for explaining a concentration change of a first impurity element along SCAN LINE 1 of FIG. 4.

FIG. 8 is a diagram for explaining the concentration change of the first impurity element along SCAN LINE 2 of FIG. 4.

FIGS. 9 and 10 are diagrams for explaining a semiconductor memory device according to some example embodiments.

FIGS. 11 to 13 are diagrams for explaining a semiconductor memory device according to some example embodiments.

FIGS. 14 and 15 are diagrams for explaining a semiconductor memory device according to some example embodiments.

FIGS. 16 and 17 are diagrams for explaining a semiconductor memory device according to some example embodiments.

FIGS. 18 and 19 are diagrams for explaining a semiconductor memory device according to some example embodiments.

FIGS. 20 and 21 are diagrams for explaining a semiconductor memory device according to some example embodiments.

FIGS. 22 to 25 are diagrams for explaining a semiconductor memory device according to some example embodiments.

FIG. 26 is a layout diagram for explaining a semiconductor memory device according to some example embodiments.

FIG. 27 is a layout showing only the third word line and the cell active region of FIG. 26.

FIGS. 28 to 30 are cross-sectional views taken along E-E, F-F, and G-G of FIG. 26.

FIG. 31 is an enlarged view for explaining the third word line, the second gate insulating film, the second gate metal oxide film of FIGS. 29 and 30.

FIGS. 32 to 64 are intermediate stage diagrams for explaining a method for fabricating a semiconductor memory device according to some example embodiments.

FIGS. 65 to 69 are intermediate stage diagrams for explaining a method for fabricating a semiconductor memory device according to some example embodiments.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

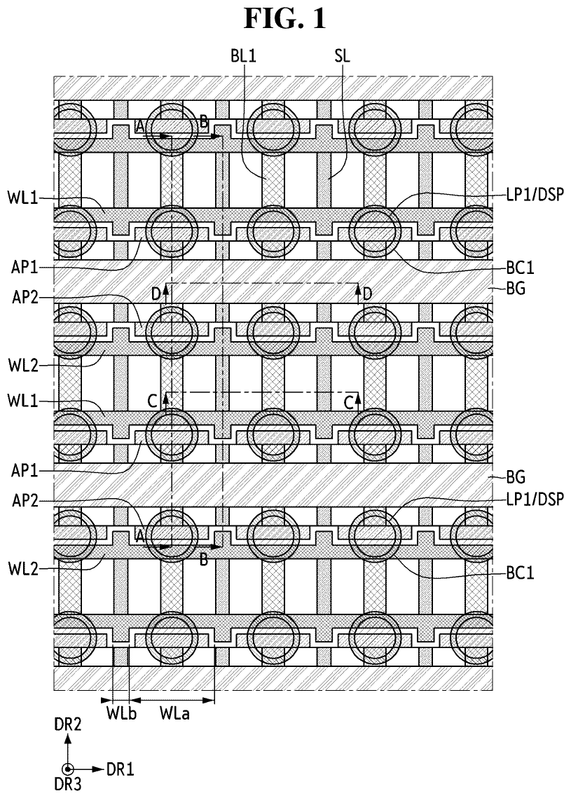

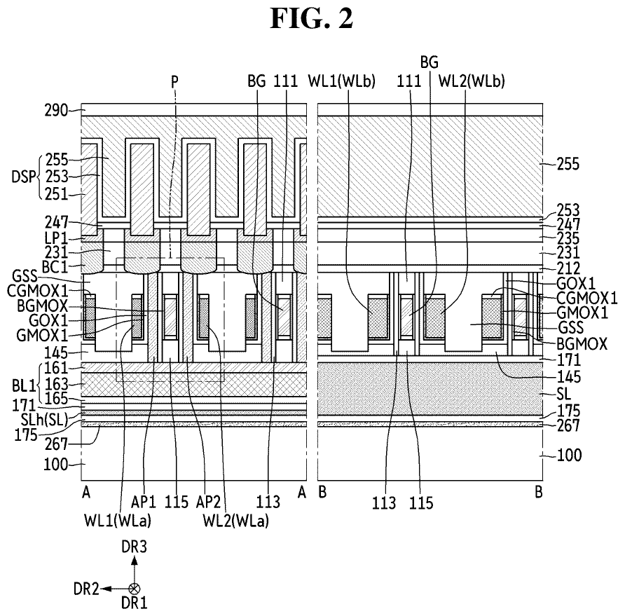

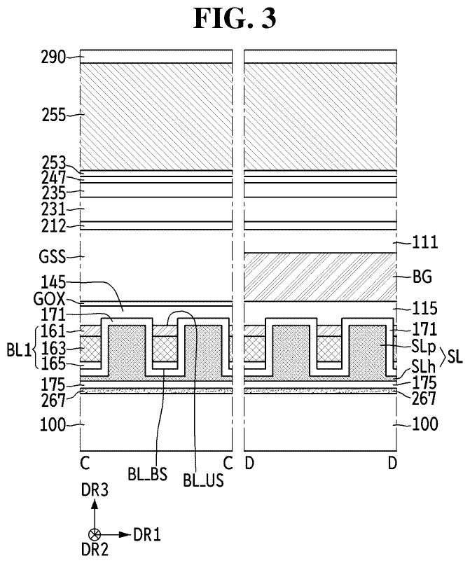

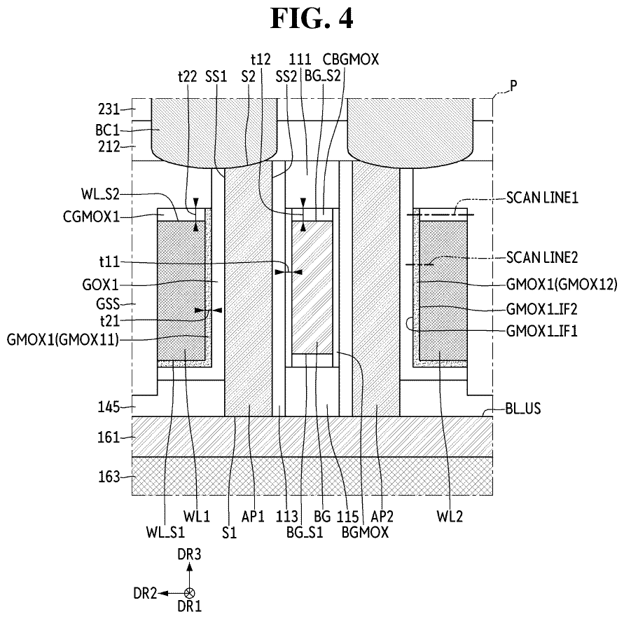

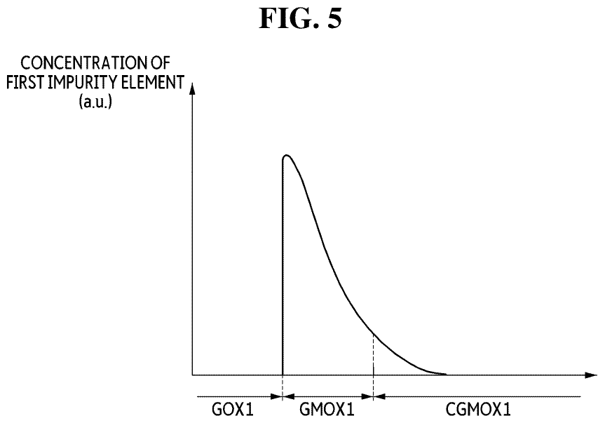

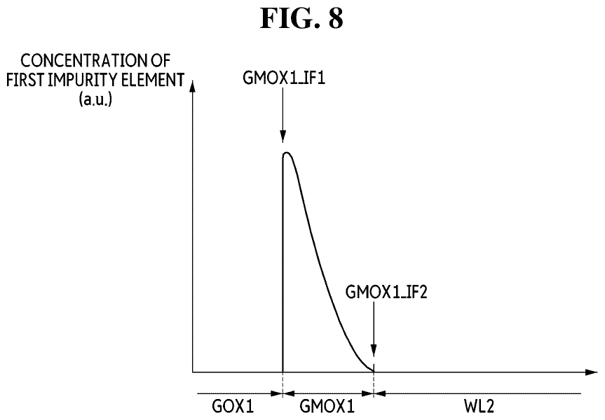

FIG. 1 is a layout diagram for explaining a semiconductor memory device according to an example embodiment. FIG. 2 is a cross-sectional view taken along A-A and B-B of FIG. 1. FIG. 3 is a cross-sectional view taken along C-C and D-D of FIG. 1. FIG. 4 is an enlarged view of a portion P of FIG. 2. FIGS. 5 to 7 are diagrams for explaining a concentration change of a first impurity element along SCAN LINE 1 of FIG. 4. FIG. 8 is a diagram for explaining the concentration change of the first impurity element along SCAN LINE 2 of FIG. 4.

The semiconductor memory device according to some example embodiments of the present disclosure may include memory cells including a vertical channel transistor (VCT).

Referring to FIGS. 1 to 8, the semiconductor memory device according to some example embodiments may include first bit lines BL1, first word lines WL1, second word lines WL2, first gate metal oxide films GMOX1, first capping gate metal oxide films CGMOX1, back gate electrodes BG, a shielding conductive pattern SL, first active patterns AP1, second active patterns AP2, and data storage patterns DSP.

The substrate 100 may be a silicon substrate or may include other materials, for example, but not limited to, silicon germanium, indium antimonide, lead telluride, indium arsenide, indium phosphide, gallium arsenide or gallium antimonide.

Although not shown, the substrate 100 may include a cell array region in which the data storage pattern DSP is disposed, and a peripheral circuit region defined around the cell array region.

A bonding insulating film 267 may be disposed on the substrate 100. The bonding insulating film 267 may be used to bond the wafer. As an example, the bonding insulating film 267 may include silicon carbonitride (SiCN). As another example, the bonding insulating film 267 may include silicon oxide (SiO₂).

Shielding structures 171, SL, and 175 may be disposed on the substrate 100. For example, the shielding structures 171, SL, and 175 may be disposed on the bonding insulating film 267.

The shielding structures 171, SL, and 175 may include a shielding conductive pattern SL and shielding insulating films 171 and 175. For example, the shielding insulating films 171 and 175 may include a shielding insulating liner 171 and a shielding insulating capping film 175.

The shielding conductive pattern SL may include a shielding conductive plate SLh and a plurality of shielding conductive line patterns SLp. The shielding conductive plate SLh may have a flat plate shape.

Each shielding conductive line pattern SLp may extend in a second direction DR2. Shielding conductive line patterns SLp may be adjacent to each other in a first direction DR1. The shielding conductive line pattern SLp may protrude from the shielding conductive plate SLh in a third direction DR3. The shielding conductive line pattern SLp is directly connected to the shielding conductive plate SLh.

For example, the first direction DR1 and the second direction DR2 may be a horizontal direction that is horizontal to the substrate 100. The third direction DR3 may be a vertical direction that is perpendicular to the substrate 100.

The shielding conductive plate SLh and each shielding conductive line pattern SLp may extend from the cell array region to the peripheral circuit region. A part of the shielding conductive pattern SL may be disposed on the peripheral circuit region, but is not limited thereto.

The shielding conductive pattern SL includes a conductive material. The shielding conductive pattern SL may include, for example, at least one of conductive metal nitride, conductive metal silicon nitride, metal carbonitride, conductive metal silicide, conductive metal oxide, a two-dimensional material, or metal.

The shielding insulating capping film 175 may be disposed on the substrate 100. For example, the shielding insulating capping film 175 may be disposed between the substrate 100 and the shielding conductive pattern SL.

The shielding insulating capping film 175 may come into contact with the shielding conductive pattern SL. In the semiconductor memory device according to some example embodiments, the shielding insulating capping film 175 may come into contact with the shielding conductive plate SLh.

The shielding insulating liner 171 may be disposed on the shielding conductive pattern SL. The shielding insulating liner 171 may be disposed between the first bit line BL1 and the substrate 100. The shielding insulating liner 171 may extend along the profile of the shielding conductive plate SLh and the shielding conductive line pattern SLp.

Each of the shielding insulating liner 171 and the shielding insulating capping film 175 may be made of or include an insulating material. When the shielding insulating liner 171 and the shielding insulating capping film 175 include the same material, a boundary between the shielding insulating liner 171 and the shielding insulating capping film 175 may not be distinguished.

Because the shielding structures 171, SL, and 175 are disposed between the first bit lines BL1 adjacent to each other in the first direction DR1, a coupling noise between the first bit lines BL1 may be reduced.

Unlike the shown example, the semiconductor memory device according to some embodiments may not include the shielding conductive pattern SL.

The first bit lines BL1 may be disposed on the substrate 100. For example, the first bit lines BL1 may be disposed on the bonding insulating film 267.

The first bit line BL1 may extend long in the second direction DR2. Adjacent first bit lines BL1 may be spaced apart from each other in the first direction DR1. The first bit line BL1 includes a long side wall extending in the second direction DR2, and a short side wall extending in the first direction DR1.

The first bit line BL1 may be disposed on the shielding conductive pattern SL. The first bit line BL1 may be disposed on the shielding conductive plate SLh.

The first bit line BL1 may be disposed to be adjacent to the shielding conductive line pattern SLp in the first direction DR1. In other words, the shielding conductive line pattern SLp may extend in the second direction DR2 along the long side wall of the first bit line BL1.

The first bit line BL1 may be disposed between the shielding conductive line patterns SLp adjacent to each other in the first direction DR1. The first bit line BL1 may be disposed on the shielding insulating liner 171. For example, the shielding insulating liner 171 may come into contact with the first bit line BL1.

Although not shown, each first bit line BL1 may extend from the cell array region to the peripheral circuit region. A part of each first bit line BL1 may be disposed on the peripheral circuit region.

The first bit line BL1 may include an upper surface BL_US and a bottom surface BL_BS that are opposite to each other in the third direction DR3. The upper surface BL_US of the first bit line may face a first active pattern AP1 and a second active pattern AP2, which will be described below.

In the semiconductor memory device according to some example embodiments, the shielding conductive pattern SL may be disposed on the bottom surface BL_BS of the first bit line BL1. For example, the shielding conductive plate SLh may be disposed on the bottom surface BL_BS of the first bit line BL1.

Each first bit line BL1 may include a semiconductor pattern 161, a metal pattern 163, and a bit line pattern mask 165, which are stacked in order. Unlike the shown example, as an example, the first bit line BL1 may include one of the semiconductor pattern 161 or the metal pattern 163. As another example, the first bit line BL1 may not include the bit line pattern mask 165.

The first bit line BL1 may include a conductive bit line. The conductive bit line includes a film made of a conductive material in the first bit line BL1. The conductive bit line may include a semiconductor pattern 161 and a metal pattern 163.

The semiconductor pattern 161 may include a conductive semiconductor material. The conductive semiconductor material may include, for example, a semiconductor material doped with impurities. The semiconductor pattern 161 may include at least one of polysilicon, polysilicon germanium, poly germanium, amorphous silicon, amorphous silicon germanium, or amorphous germanium.

The metal pattern 163 may include a conductive material including metal. The metal pattern 163 may include, for example, at least one of conductive metal nitride, conductive metal silicon nitride, metal carbonitride, conductive metal silicide, conductive metal oxide, a two-dimensional material, or metal. In the semiconductor device according to some example embodiments, the two-dimensional material may be a metallic material and/or a semiconductor material. The 2D material may include a 2D allotrope or a 2D compound, and may include, for example, but not limited to, at least one of graphene, molybdenum disulfide (MoS₂), molybdenum diselenide (MoSe₂), tungsten diselenide (WSe₂), or tungsten disulfide (WS₂). That is, because the above-mentioned 2D materials are only listed as an example, the 2D materials that may be included in the semiconductor memory device of the present disclosure are not limited by the above-mentioned materials.

The bit line pattern mask 165 may include an insulating material. The bit line pattern mask 165 may include, but not limited to, silicon nitride, silicon oxynitride or the like.

The first active patterns AP1 and the second active patterns AP2 may be disposed on the respective first bit lines BL1. The first active patterns AP1 and the second active patterns AP2 may be disposed alternately along the second direction DR2.

The first active patterns AP1 may be spaced apart from each other in the first direction DR1. The first active patterns AP1 may be spaced apart at regular intervals. The second active patterns AP2 may be spaced apart from each other in the first direction DR1. The second active patterns AP2 may be spaced apart at regular intervals. The first active pattern AP1 may be spaced apart from the second active pattern AP2 in the second direction DR2. The first active patterns AP1 and the second active patterns AP2 may be arranged two-dimensionally along the first direction DR1 and the second direction DR2 that intersect each other.

Each of the first active pattern AP1 and the second active pattern AP2 may be a channel region. For example, each of the first active pattern AP1 and the second active pattern AP2 may be made of or include a single crystal semiconductor material. As an example, each of the first active pattern AP1 and the second active pattern AP2 may be made of single crystal silicon. Each of the first active pattern AP1 and the second active pattern AP2 may be a silicon active pattern.

Each of the first active pattern AP1 and the second active pattern AP2 may have a length in the first direction DR1, a width in the second direction DR2, and a height in the third direction DR3. Each of the first active pattern AP1 and the second active pattern AP2 may have a substantially uniform width. That is, each of the first active pattern AP1 and the second active pattern AP2 may have substantially the same width on the first and second faces S1 and S2. In addition, the width of the first active pattern AP1 may be equal to the width of the second active pattern AP2.

The width of the first active pattern AP1 and the width of the second active pattern AP2 may be several nm to several tens of nm. For example, the width of the first active pattern AP1 and the width of the second active pattern AP2 may be, but not limited to, 1 nm to 30 nm, for example, 1 nm to 10 nm. The length of each of the first active pattern AP1 and the second active pattern AP2 may be greater than a line width of the first bit line BL1. That is, the length of each of the first active pattern AP1 and the second active pattern AP2 may be greater than the width of the first bit line BL1 in the first direction DR1.

In FIG. 4, each of the first active pattern AP1 and the second active pattern AP2 includes a first surface S1 and a second surface S2 that are opposite to each other in the third direction DR3. For example, the first surface S1 of each of the first active pattern AP1 and the second active pattern AP2 may face the first bit line BL1. The second surface S2 of each of the first active pattern AP1 and the second active pattern AP2 may face a first contact pattern BC1.

The first surfaces S1 of each of the first active pattern AP1 and the second active pattern AP2 are connected to the first bit line BL1. For example, the first surfaces S1 of each of the first active patterns AP1 and the second active patterns AP2 may be connected to the semiconductor pattern 161 of the first bit line BL1. Unlike the shown example, when the semiconductor pattern 161 is omitted, the first surfaces S1 of each of the first active patterns AP1 and the second active patterns AP2 may be connected to the metal pattern 163. The second surfaces S2 of each of the first active patterns AP1 and the second active patterns AP2 may be connected to the first contact pattern BC1.

Each of the first active pattern AP1 and the second active pattern AP2 may include a first side wall SS1 and a second side wall SS2 that are opposite to each other in the second direction DR2. The second side wall SS2 of the first active pattern AP1 may face the first side wall SS1 of the second active pattern AP2.

The first side wall SS1 of the first active pattern AP1 may be adjacent to a first word line WL1. The second side wall SS2 of the second active pattern AP2 may be adjacent to a second word line WL2.

Although not shown, as an example, each of the first active pattern AP1 and the second active pattern AP2 may include a first dopant portion adjacent to the first bit line BL1, and a second dopant portion adjacent to the first contact pattern BC1. Each of the first active pattern AP1 and the second active pattern AP2 may include a channel portion between the first dopant portion and the second dopant portion. The first dopant portion and the second dopant portion are regions in which dopants are doped inside the first active pattern AP1 and the second active pattern AP2. Unlike the above example, each of the first active pattern AP1 and the second active pattern AP2 may not include at least one of the first dopant portion or the second dopant portion.

When the semiconductor memory device operates, the channel portions of the first active pattern AP1 and the second active pattern AP2 may be controlled by the first and second word lines WL1 and WL2 and the back gate electrode BG. Because the first active pattern AP1 and the second active pattern AP2 are made of a single crystal semiconductor material, the leakage current characteristics of the semiconductor memory device may be improved.

The back gate electrodes BG may be disposed on the first bit line BL1 and the shielding conductive pattern SL. The back gate electrodes BG may be spaced apart from each other in the second direction DR2. The back gate electrodes BG may be spaced apart at regular intervals. Each back gate electrode BG may extend in the first direction DR1 across the first bit line BL1.

Each back gate electrode BG may be disposed between the first active pattern AP1 and the second active pattern AP2 that are adjacent to each other in the second direction DR2. That is to say, the first active pattern AP1 may be disposed on one side of each back gate electrode BG, and the second active pattern AP2 may be disposed on the other side of each back gate electrode BG. Each back gate electrode BG may be disposed between the second side wall SS2 of the first active pattern AP1 and the first side wall SS1 of the second active pattern AP2. The height of the back gate electrode BG in the third direction DR3 may be smaller than the height of the first active pattern AP1 and the second active pattern AP2.

The first active pattern AP1 may be disposed between the first word line WL1 and the back gate electrode BG. The second active pattern AP2 may be disposed between the second word line WL2 and the back gate electrode BG. A pair of first word line WL1 and second word line WL2 may be disposed between the back gate electrodes BG adjacent to each other in the second direction DR2.

The back gate electrode BG may include a first surface BG_S1 and a second surface BG_S2 that are opposite to each other in the third direction DR3. The first surface BG_S1 of the back gate electrode is closer to the first bit line BL1 than the second surface BG_S2 of the back gate electrode. The first surface BG_S1 of the back gate electrode may face the first bit line BL1.

The back gate electrode BG includes a conductive material, and may include, for example, at least one of a conductive semiconductor material, conductive metal nitride, conductive metal silicon nitride, metal carbonitride, conductive metal silicide, a two-dimensional material, or metal.

In the semiconductor memory device according to some embodiments, the back gate electrode BG may include a first metal element. For example, the first metal element may be titanium (Ti). The back gate electrode BG may include titanium nitride (TiN).

A voltage is applied to the back gate electrode BG at the time of the operation of the semiconductor memory device, and a threshold voltage of the vertical channel transistor may be adjusted. Because the threshold voltage of the vertical channel transistor is adjusted, degradation of leakage current characteristics can be reduced or prevented.

The back gate separation pattern 111 may be disposed between the first active pattern AP1 and the second active pattern AP2 that are adjacent to each other in the second direction D2. The back gate separation pattern 111 may extend in the first direction D1 alongside of the back gate electrode BG. The back gate separation pattern 111 may be disposed on the second surface BG_S2 of the back gate electrode.

The back gate separation pattern 111 may be made of or include an insulating material. The back gate separation pattern 111 may include, for example, but not limited to, a silicon oxide film, a silicon oxynitride film or a silicon nitride film.

The back gate insulating film 113 may be disposed between the back gate electrode BG and the first active pattern AP1, and between the back gate electrode BG and the second active pattern AP2. The back gate insulating film 113 may be disposed between the back gate separation pattern 111 and the first active pattern AP1, and between the back gate separation pattern 111 and the second active pattern AP2.

The back gate insulating film 113 may extend along the second side wall SS2 of the first active pattern AP1 and the first side wall SS1 of the second active pattern AP2. The back gate insulating film 113 may come into contact with the first active pattern AP1 and the second active pattern AP2.

The back gate insulating film 113 may be made of or include an insulating material. The back gate insulating film 113 may include, but not limited to, silicon oxide.

The back gate capping pattern 115 may be disposed between the first bit line BL1 and the back gate electrode BG. The back gate capping pattern 115 may be disposed between the first active pattern AP1 and the second active pattern AP2 that are adjacent to each other in the second direction DR2. The back gate capping pattern 115 may extend in the first direction DR1 alongside of the back gate electrode BG. The back gate capping pattern 115 may be disposed on the first surface BG_S1 of the back gate electrode. A thickness of the back gate capping pattern 115 between the first bit lines BL1 may be different from the thickness of the back gate capping pattern 115 on the upper surface BL_US of the first bit line, but example embodiments are not limited thereto.

The back gate capping pattern 115 may be made of an insulating material. The back gate capping pattern 115 may include, for example, but example embodiments are not limited to, at least one of a silicon oxide film, a silicon oxynitride film, or a silicon nitride film.

A back gate metal oxide film BGMOX may be disposed between the back gate electrode BG and the back gate insulating film 113. The back gate metal oxide film BGMOX may be disposed between the back gate electrode BG and the first active pattern AP1, and between the back gate electrode BG and the second active pattern AP2.

The back gate metal oxide film BGMOX may extend along a side wall of the back gate electrode BG extending in the third direction DR3. The back gate metal oxide film BGMOX may extend along a boundary between the back gate electrode BG and the back gate insulating film 113. For example, the back gate metal oxide film BGMOX may come into contact with the back gate electrode BG and the back gate insulating film 113.

A back gate capping metal oxide film CBGMOX may be disposed between the back gate electrode BG and the back gate capping pattern 115. The back gate capping metal oxide film CBGMOX may be disposed between the back gate electrode BG and the back gate separation pattern 111.

The back gate capping metal oxide film CBGMOX may be disposed on the first surface BG_S1 of the back gate electrode BG. The back gate capping metal oxide film CBGMOX may be disposed on the second surface BG_S2 of the back gate electrode BG. The back gate capping metal oxide film CBGMOX may be in contact with the back gate electrode BG. The back gate capping metal oxide film CBGMOX may be disposed between the back gate metal oxide films BGMOX.

For example, the back gate metal oxide film BGMOX and the back gate capping metal oxide film CBGMOX may include first metal oxide. The first metal oxide may be oxide of a first metal element included in the back gate electrode BG. When the back gate electrode BG includes titanium nitride (TiN), the first metal oxide may be titanium oxide. The back gate metal oxide film BGMOX and the back gate capping metal oxide film CBGMOX may include titanium oxide.

Because the back gate metal oxide film BGMOX and the back gate capping metal oxide film CBGMOX include the same material, a boundary between the back gate metal oxide film BGMOX and the back gate capping metal oxide film CBGMOX may not be distinguished. The boundary between the back gate metal oxide film BGMOX and the back gate capping metal oxide film CBGMOX may be distinguish by utilizing a thickness t11 of the back gate metal oxide film BGMOX extending along the boundary between the back gate electrode BG and the back gate insulating film 113.

A thickness t12 of the back gate capping metal oxide film CBGMOX in the third direction DR3 is different from the thickness t11 of the back gate metal oxide film BGMOX in the second direction DR2. For example, the thickness t12 of the back gate capping metal oxide film CBGMOX may be greater than the thickness t11 of the back gate metal oxide film BGMOX.

The first word line WL1 and the second word line WL2 may be disposed on the first bit line BL1 and the shielding conductive pattern SL. Each of the first word line WL1 and the second word line WL2 may extend in the first direction DR1. The first word line WL1 and the second word line WL2 may be arranged alternately in the second direction DR2.

The first word line WL1 may be disposed on the first side wall SS1 of the first active patterns AP1. The second word line WL2 may be disposed on the second side wall SS2 of the second active patterns AP2. The first active patterns AP1 and the second active patterns AP2 may be disposed between the first word line WL1 and the second word line WL2 that are adjacent to each other in the second direction DR2.

In the semiconductor memory device according to some example embodiments, the first word line WL1 and the second word line WL2 may be spaced apart from the first bit line BL1 and the first contact pattern BC1 in the third direction DR3. The first word line WL1 and the second word line WL2 may be located between the first bit line BL1 and the first contact pattern BC1.

Each of the first word line WL1 and the second word line WL2 may have a width in the second direction DR2. As an example, the width of the first word line WL1 and the width of the second word line WL2 on the first bit line BL1 may be different from the width of the first word line WL1 and the width of the second word line WL2 on the shielding conductive line pattern SLp.

For example, each of the first word line WL1 and the second word line WL2 may include a first portion WLa of the word line, and a second portion WLb of the word line. A width of the first portion WLa of the word line in the second direction DR2 may be smaller than a width of the second portion WLb of the word line in the second direction DR2. As an example, the first portion WLa of the word line may be disposed on the first bit line BL1. The second portion WLb of the word line may be disposed on the shielding conductive line pattern SLp.

Each of the first word line WL1 and the second word line WL2 may include the first portion WLa of the word line and the second portion WLb of the word line that are disposed alternately along the first direction DR1. In the first word line WL1, each first active pattern AP1 may be disposed between the second portions WLb of the word lines adjacent to each other in the first direction DR1. In the second word line WL2, each second active pattern AP2 may be disposed between the second portions WLb of the word lines adjacent to each other in the first direction DR1.

Unlike the shown example, the width of the first portion WLa of the word line in the second direction DR2 may be equal to the width of the second portion WLb of the word line in the second direction DR2. In other words, the width of the first word line WL1 and the width of the second word line WL2 on the first bit line BL1 may be equal to the width of the first word line WL1 and the width of the second word line WL2 on the shielding conductive line pattern SLp. In such a case, a first gate insulating film GOX1 to be described below may fill a space between the first active patterns AP1 adjacent to each other in the first direction DR1 and the space between the second active patterns AP2 adjacent to each other in the first direction DR1.

The first word line WL1 and the second word line WL2 may include a first surface WL_S1 and a second surface WL_S2 that are opposite to each other in the third direction DR3. The first surfaces WL_S1 of the first and second word lines is closer to the first bit line BL1 than the second surfaces WL_S2 of the first and second word lines. The first surfaces WL_S1 of the first and second word lines faces the first bit line BL1.

As an example, the first surfaces WL_S1 of each of the first and second word lines WL1 and WL2 may be the bottom surface thereof. The second surfaces WL_S2 of each of the first and second word lines WL1 and WL2 may be the upper surface thereof. As another example, the first surfaces WL_S1 of each of the first and second word lines WL1 and WL2 may be the upper surface thereof. The second surfaces WL_S2 of each of the first and second word lines WL1 and WL2 may be the bottom surface thereof.

The first word line WL1 will be explained as an example. As an example, a height of the first word line WL1 in the third direction DR3 may be equal to a height of the back gate electrode BG in the third direction DR3. As another example, the height of the first word line WL1 in the third direction DR3 may be greater than the height of the back gate electrode BG in the third direction DR3. As yet another example, the height of the first word line WL1 in the third direction DR3 may be smaller than the height of the back gate electrode BG in the third direction DR3.

Also, as an example, the height of the first surface WL_S1 of the first word line may be equal to the height of the first surface BG_S1 of the back gate electrode, on the basis of the upper surface BL_US of the first bit line. As another example, the first surface WL_S1 of the first word line may be higher than the first surface BG_S1 of the back gate electrode. As yet another example, the first surface WL_S1 of the first word line may be lower than the first surface BG_S1 of the back gate electrode.

In addition, as an example, the height of the second surface WL_S2 of the first word line may be equal to the height of the second surface BG_S2 of the back gate electrode, on the basis of the upper surface BL_US of the first bit line. As another example, the second surface WL_S2 of the first word line may be higher than the second surface BG_S2 of the back gate electrode. As yet another example, the second surface WL_S2 of the first word line may be lower than the second surface BG_S2 of the back gate electrode.

The first surfaces WL_S1 of the first and second word lines WL1 and WL2 may be, but example embodiments are not limited to, a plane. The second surface WL_S2 of the first and second word lines WL1 and WL2 may be, but example embodiments are not limited to, a plane. The first surface BG_S1 of the back gate electrode and the second surface BG_S2 of the back gate electrode are shown as being a plane, but example embodiments are not limited thereto.

The first word line WL1 and the second word line WL2 may include a conductive material. The first word line WL1 and the second word line WL2 may include, for example, at least one of a conductive semiconductor material, conductive metal nitride, conductive metal silicon nitride, metal carbonitride, conductive metal silicide, a two-dimensional material, or metal.

In the semiconductor memory device according to some example embodiments, the first word line WL1 and the second word line WL2 may include a second metal element. For example, the second metal element may be titanium (Ti). Each of the first word line WL1 and the second word line WL2 may include titanium nitride (TiN).

The first gate insulating films GOX1 may be disposed between the first word line WL1 and the first active pattern AP1, and between the second word line WL2 and the second active pattern AP2. The first gate insulating film GOX1 may extend in the first direction DR1 alongside of the first word line WL1 and the second word line WL2.

The first gate insulating film GOX1 may extend along the first side wall SS1 of the first active pattern AP1, and may extend along the second side wall SS2 of the second active pattern AP2. The first gate insulating film GOX1 may come into contact with the first active pattern AP1 and the second active pattern AP2.

The first gate insulating film GOX1 may extend along the first surfaces WL_S1 of the first and second word lines WL1 and WL2. The first gate insulating film GOX1 may not extend along the second surfaces WL_S2 of the first and second word lines WL1 and WL2.

Unlike the shown example, the first gate insulating film GOX1 may extend along the second surfaces WL_S2 of the first and second word lines WL1 and WL2. The first gate insulating film GOX1 may not extend along the first surface WL_S1 of the first and second word lines WL1 and WL2.

The first gate insulating film GOX1 may be made of or include an insulating material. The first gate insulating film GOX1 may include, for example, but example embodiments are not limited to, silicon oxide.

The first gate metal oxide film GMOX1 may be disposed between the first word line WL1 and the first active pattern AP1, and between the second word line WL2 and the second active pattern AP2. The first gate metal oxide film GMOX1 may be disposed between the first word line WL1 and the first gate insulating film GOX1, and between the second word line WL2 and the first gate insulating film GOX1.

The first gate metal oxide film GMOX1 may extend along the first surfaces WL_S1 of the first and second word lines WL1 and WL2. The first gate metal oxide film GMOX1 may come into contact with the first surfaces WL_S1 of the first and second word lines WL1 and WL2. The first gate metal oxide film GMOX1 may not extend along the second surfaces WL_S2 of the first and second word lines WL1 and WL2.

Unlike the shown example, when the first gate insulating film GOX1 extends along the second surfaces WL_S2 of the first and second word lines WL1 and WL2, the first gate metal oxide film GMOX1 may extend along the second surfaces WL_S2 of the first and second word lines WL1 and WL2. The first gate metal oxide film GMOX1 may come into contact with the second surfaces WL_S2 of the first and second word lines WL1 and WL2. When the first gate insulating film GOX1 does not extend along the first surfaces WL_S1 of the first and second word lines WL1 and WL2, the first gate metal oxide film GMOX1 may not extend along the first surfaces WL_S1 of the first and second word lines WL1 and WL2.

The first gate metal oxide film GMOX1 may extend along a boundary between the first word line WL1 and the first gate insulating film GOX1, and a boundary between the second word line WL2 and the first gate insulating film GOX1. For example, the first gate metal oxide film GMOX1 may come into contact with the first word line WL1 and the second word line WL2. In the semiconductor memory device according to some example embodiments, the first gate metal oxide film GMOX1 may come into contact with the first gate insulating film GOX1.

The first gate metal oxide film GMOX1 may include a first sub-gate metal oxide film GMOX11 and a second sub-gate metal oxide film GMOX12. The first sub-gate metal oxide film GMOX11 may extend along the boundary between the first word line WL1 and the first gate insulating film GOX1. The first sub-gate metal oxide film GMOX11 may come into contact with the first word line WL1. The second sub-gate metal oxide film GMOX12 may extend along the boundary between the second word line WL2 and the first gate insulating film GOX1. The second sub-gate metal oxide film GMOX12 may come into contact with the second word line WL2.

A first capping gate metal oxide film CGMOX1 may be disposed on the second surfaces WL_S2 of the first and second word lines WL1 and WL2. The first capping gate metal oxide film CGMOX1 may come into contact with the first and second word lines WL1 and WL2.

The first capping gate metal oxide film CGMOX1 may not be disposed on the first surfaces WL_S1 of the first and second word lines WL1 and WL2. The first capping gate metal oxide film CGMOX1 may not be disposed along the boundary between the first word line WL1 and the first gate insulating film GOX1. The first capping gate metal oxide film CGMOX1 may not be disposed along the boundary between the second word line WL2 and the first gate insulating film GOX1.

For example, the first gate metal oxide film GMOX1 and the first capping gate metal oxide film CGMOX1 may include second metal oxide. The second metal oxide may be oxide of a second metal element included in the first word line WL1 and the second word line WL2. When the first word line WL1 and the second word line WL2 include titanium nitride (TiN), the second metal oxide may be titanium oxide. The first gate metal oxide film GMOX1 and the first capping gate metal oxide film CGMOX1 may include titanium oxide.

Because the first gate metal oxide film GMOX1 and the first capping gate metal oxide film CGMOX1 include the same material, the boundary between the first gate metal oxide film GMOX1 and the first capping gate metal oxide film CGMOX1 may not be distinguished. The boundary between the first gate metal oxide film GMOX1 and the first capping gate metal oxide film CGMOX1 may be distinguished, by using a thickness t21 of the first gate metal oxide film GMOX1 extending along the boundary between the word lines WL1 and WL2 and the first gate insulating film GOX1.

A thickness t22 of the first capping gate metal oxide film CGMOX1 in the third direction DR3 is different from the thickness t21 of the first gate metal oxide film GMOX1 in the second direction DR2. For example, the thickness t22 of the first capping gate metal oxide film CGMOX1 may be greater than the thickness t21 of the first gate metal oxide film GMOX1.

The first gate metal oxide film GMOX1 may include a doped first impurity element. The first impurity element may include, for example, at least one of niobium (Nb), tantalum (Ta), vanadium (V), zirconium (Zr), aluminum (Al), molybdenum (Mo), cobalt (Co), phosphorus (P), nitrogen (N), or arsenic (As).

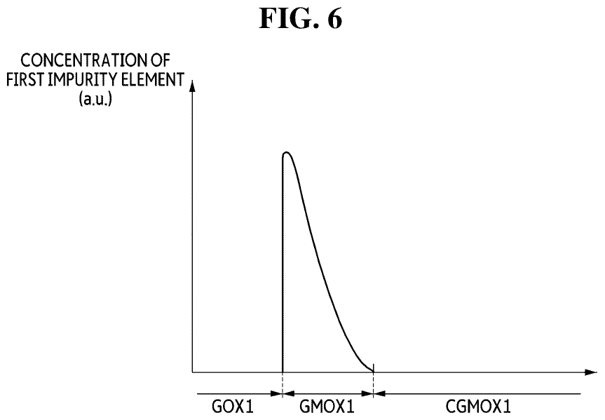

In FIGS. 5 and 6, the first gate insulating film GOX1 may not include the first impurity element. In the first gate insulating film GOX1, the concentration (/cm³) of the first impurity element may be 0. Here, the concentration of the impurity element being “0” may mean that the impurity element is not present inside the film or that an amount smaller than a detection limit of a measurement device is present.

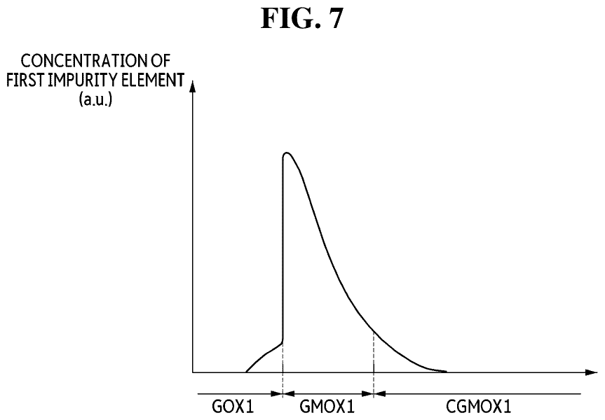

In FIG. 7, the first gate insulating film GOX1 may include the first impurity element.

In FIGS. 5 and 7, the first capping gate metal oxide film CGMOX1 may include the first impurity element. The concentration of the first impurity element in the first capping gate metal oxide film CGMOX1 may decrease, as it goes away from the first gate metal oxide film GMOX1 in the second direction DR2. The concentration of the first impurity element in the first capping gate metal oxide film CGMOX1 may decrease, as it goes away from the first gate insulating film GOX1 in the second direction DR2. The first impurity element included in the first capping gate metal oxide film CGMOX1 may be, but example embodiments are not limited to, obtained by movement of the first impurity element included in the first gate metal oxide film GMOX1 through a diffusion.

In FIG. 6, the first capping gate metal oxide film CGMOX1 may not include the first impurity element.

The concentration of the first impurity element in the first gate metal oxide film GMOX1 is different from the concentration of the first impurity element in the first capping gate metal oxide film CGMOX1. The concentration of the first impurity element in the first gate metal oxide film GMOX1 is greater than the concentration of the first impurity element in the first capping gate metal oxide film CGMOX1. As an example, the concentration of the first impurity element in the first capping gate metal oxide film CGMOX1 may be an average concentration from the viewpoint of a cross-sectional view such as FIG. 4. As another example, the concentration of the first impurity element in the first capping gate metal oxide film CGMOX1 may be, but example embodiments are not limited to, a value measured in the vicinity of the center of the width of the first capping gate metal oxide film CGMOX1 in the second direction DR2.

The first gate metal oxide film GMOX1 may include a first interface GMOX1_IF1 and a second interface GMOX1_IF2 that are opposite to each other. The first interface GMOX1_IF1 of the first gate metal oxide film may face the first gate insulating film GOX1. The second interface GMOX1_IF2 of the first gate metal oxide film may face the first and second word lines WL1 and WL2.

In FIG. 8, the concentration of the first impurity element may be a first impurity concentration at the first interface GMOX1_IF1 of the first gate metal oxide film. The concentration of the first impurity element may be a second impurity concentration smaller than the first impurity concentration at the second interface GMOX1_IF2 of the first gate metal oxide film. The concentration of the first impurity element at the first interface GMOX1_IF1 of the first gate metal oxide film may be greater than the concentration of the first impurity element at the second interface GMOX1_IF2 of the first gate metal oxide film. For example, the concentration of the first impurity element included in first gate metal oxide film GMOX1 may decrease, as it goes away from the first gate insulating film GOX1.

At the time of the fabricating process, an impurity film capable of alleviating oxygen scavenging of the first gate insulating film GOX1 may be interposed between the first gate insulating film GOX1 and the first word line WL1. The impurity film capable of alleviating oxygen scavenging of the first gate insulating film GOX1 may be changed or converted to the first gate metal oxide film GMOX1. This makes it possible to reduce or prevent the insulating characteristics of the first gate insulating film GOX1 from being degraded. The performance and/or reliability of the semiconductor memory device can be improved, accordingly.

A dipole is formed due to the first impurity element included in the first gate metal oxide film GMOX1, and the work function of the gate electrode of the transistor may be adjusted. Accordingly, gate induced drain leakage (GIDL) characteristics of the transistor can be improved.

In FIG. 8, although the first and second word lines WL1 and WL2 are shown as not including the first impurity element, example embodiments are not limited thereto. Unlike the shown example, the first and second word lines WL1 and WL2 may include the first impurity element at the portion that forms the boundary with the first gate metal oxide film GMOX1.

A gate shielding pattern 145 may be disposed between the first word line WL1 and the first bit line BL1, and between the second word line WL2 and the first bit line BL1. The gate shielding pattern 145 may be disposed on the first surfaces WL_S1 of the first and second word lines WL1 and WL2.

The gate shielding pattern 145 may include an upper face and a bottom face that are opposite to each other in the third direction DR3. The bottom face of the gate shielding pattern 145 may face the first bit line BL1. The first word line WL1 and the second word line WL2 may be disposed on an upper face of the gate shielding pattern 145. The first gate insulation pattern GOX1 may extend along the upper face of the gate shielding pattern 145.

A gate separation pattern GSS may be disposed on the first bit line BL1. The gate separation pattern GSS may be disposed on the gate shielding pattern 145.

The gate separation pattern GSS may be disposed between the first word line WL1 and the second word line WL2 that are adjacent to each other in the second direction DR2. The first word line WL1 and the second word line WL2 may be separated by the gate separation pattern GSS. The gate separation pattern GSS may extend in the first direction DR1 between the first word line WL1 and the second word line WL2.

The first word line WL1 may be disposed between the gate separation pattern GSS and the first active pattern AP1. The gate separation pattern GSS may be disposed on the first side wall SS1 of the first active pattern AP1. The second word line WL2 may be disposed between the gate separation pattern GSS and the second active pattern AP2. The gate separation pattern GSS may be disposed on the second side wall SS2 of the second active pattern AP2.

Each of the gate shielding pattern 145 and the gate separation pattern GSS may be made of an insulating material. Although the gate shielding pattern 145 and/or the gate separation pattern GSS are shown as being a single film, this is only for convenience of explanation, and example embodiments are not limited thereto. Unlike the shown example, the gate shielding pattern 145 and/or the gate separation pattern GSS may include a plurality of insulating films.

The first contact patterns BC1 may penetrate a contact interlayer insulating film 231 and a contact etching stop film 212. The first contact patterns BC1 may be connected to each of the first active pattern AP1 and the second active pattern AP2. The first contact patterns BC1 may be connected to the second surface S2 of the first and second active patterns AP1 and AP2. Each of the first contact patterns BC1 may have various shapes, such as a circle, an ellipse, a rectangle, a square, a rhombus or a hexagon, from a planar point of view.

The first contact pattern BC1 may include a conductive material. The first contact pattern BC1 may include, for example, at least one of doped polysilicon, conductive metal nitride, conductive metal silicon nitride, metal carbonitride, conductive metal silicide, conductive metal oxide, a two-dimensional material, or metal.

The contact etching stop film 212 may be disposed on the gate separation pattern GSS and the back gate separation pattern 111. The contact interlayer insulating film 231 and the contact etching stop film 212 may each be made of or include an insulating material.

First landing pads LP1 may be disposed on the first contact pattern BC1. The first landing pads LP1 may have various shapes such as a circle, an ellipse, a rectangle, a square, a rhombus or a hexagon from a planar point of view.

Pad separation insulating patterns 235 may be disposed between the first landing pads LP1. The first landing pads LP1 may be arranged in a matrix shape along the first direction DR1 and the second direction DR2 from a planar point of view. The upper face of the first landing pad LP1 may be substantially coplanar with the upper face of the pad separation insulating pattern 235, but example embodiments are not limited thereto.

The first landing pad LP1 may include a conductive material, and may include, for example, at least one of a doped polysilicon, conductive metal nitride, conductive metal silicon nitride, metal carbonitride, conductive metal silicide, conductive metal oxide, a two-dimensional material, or metal.

Unlike the shown example, a semiconductor memory device according to some embodiments may not include the first landing pad LP1.

The data storage patterns DSP may be disposed on each of the first landing pads LP1. The data storage patterns DSP may be electrically connected to each of the first active pattern AP1 and the second active pattern AP2. The data storage patterns DSP may be arranged in a matrix shape along the first direction DR1 and the second direction DR2, as shown in FIG. 1. The data storage patterns DSP may completely overlap or partially overlap the first landing pads LP1 in the third direction DR3. The data storage patterns DSP may come into contact with all or a part of the upper faces of the first landing pads LP1.

As an example, the data storage patterns DSP may be capacitors. The data storage patterns DSP may include a capacitor dielectric film 253 interposed between the storage electrodes 251 and the plate electrode 255. For example, the storage electrode 251 may come into contact with the first landing pad LP1. The storage electrode 251 may have various shapes such as a circle, an ellipse, a rectangle, a square, a rhombus, and a hexagon from a planar point of view.

The data storage patterns DSP may come into contact with all or a part of the upper faces of the first landing pads LP1. The storage electrodes 251 may penetrate the upper etching stop film 247. The upper etching stop film 247 may be made of or include an insulating material. A part of the storage electrode 251 is shown to enter the first landing pad LP1, but example embodiments are not limited thereto.

Each of the storage electrode 251 and the plate electrode 255 may include, for example, at least one of a conductive semiconductor material, conductive metal nitride, conductive metal silicon nitride, metal carbonitride, conductive metal silicide, conductive metal oxide, or metal. The capacitor dielectric film 253 may include at least one of a ferroelectric material, an antiferroelectric material, or a paraelectric material. For example, the capacitor dielectric film 253 may include one of the ferroelectric material, the antiferroelectric material, the paraelectric material, combinations of the ferroelectric material and the antiferroelectric material, combinations of the ferroelectric material and the paraelectric material, combinations of the paraelectric material and the antiferroelectric material, or combinations of the ferroelectric material, the antiferroelectric material and the paraelectric material.

In contrast, the data storage patterns DSP may be variable resistance patterns that may be switched between two resistance states by electrical pulses applied to the memory element. For example, the data storage patterns DSP may include a phase-change material, perovskite compounds, a transition metal oxide, magnetic materials, ferromagnetic materials or antiferromagnetic materials.

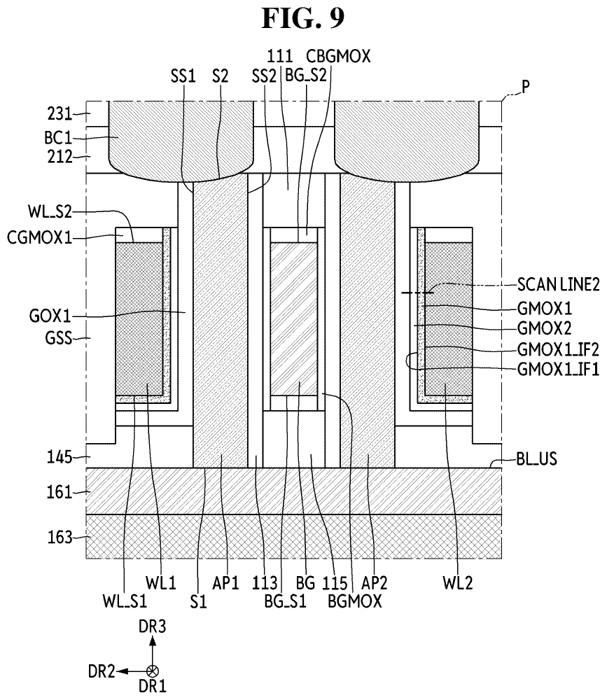

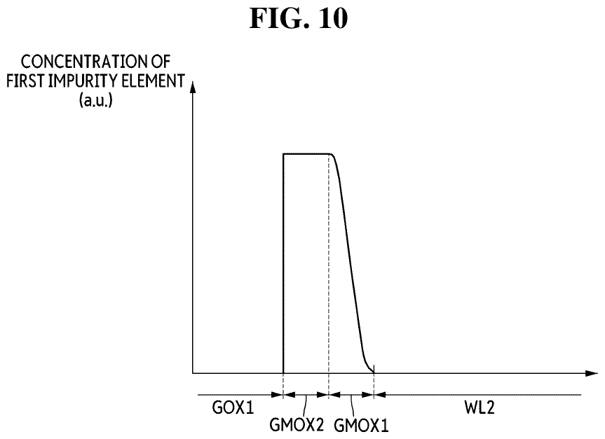

FIGS. 9 and 10 are diagrams for explaining a semiconductor memory device according to some example embodiments. For convenience of explanation, differences from contents explained using FIGS. 1 to 8 will be mainly explained.

For reference, FIG. 9 is a diagram showing an enlarged view of a portion P of FIG. 2. FIG. 10 is a diagram for explaining the concentration change of the first impurity element along SCAN LINE 2 of FIG. 9.

Referring to FIGS. 9 and 10, the semiconductor memory device according to some example embodiments may further include a second metal gate oxide film GMOX2 disposed between the first gate insulating film GOX1 and the first metal gate oxide film GMOX1.

The second metal gate oxide film GMOX2 may extend along the boundary between the first word line WL1 and the first gate insulating film GOX1, and a boundary between the second word line WL2 and the first gate insulating film GOX1. For example, the second metal gate oxide film GMOX2 may come into contact with the first gate insulating film GOX1.

The second metal gate oxide film GMOX2 may include oxide of the first impurity element doped into the first gate metal oxide film GMOX1. For example, the second metal gate oxide film GMOX2 may include at least one of niobium oxide, tantalum oxide, vanadium oxide, zirconium oxide, aluminum oxide, molybdenum oxide, or cobalt oxide.

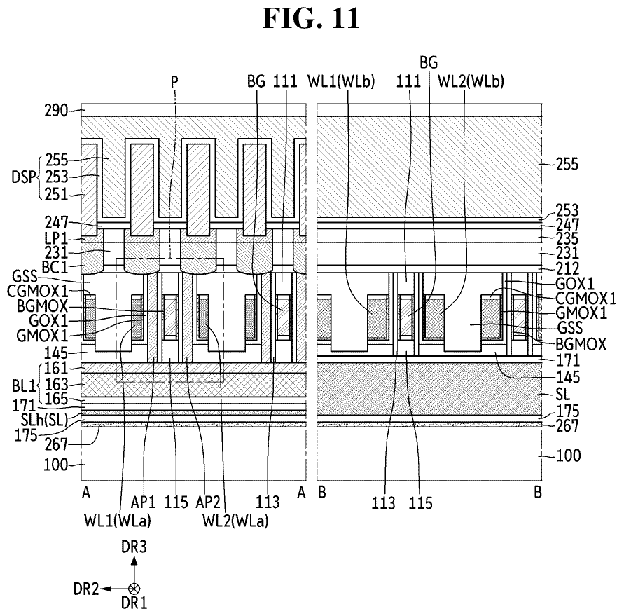

FIGS. 11 to 13 are diagrams for explaining a semiconductor memory device according to some example embodiments. For convenience of explanation, differences from contents explained using FIGS. 1 to 8 will be mainly explained.

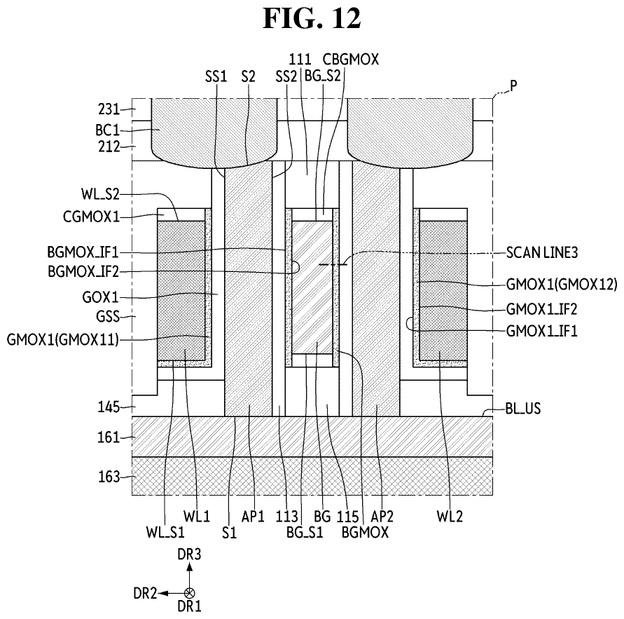

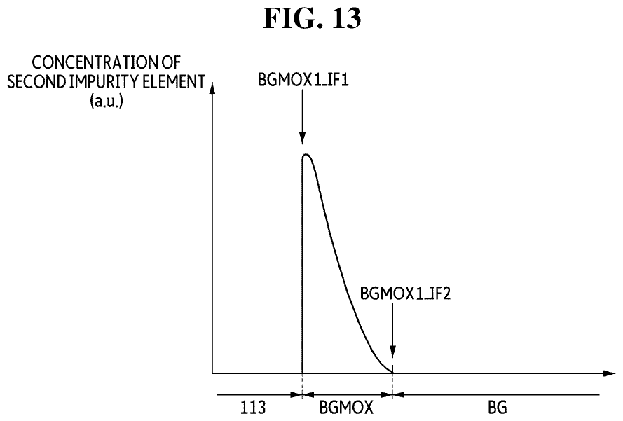

For reference, FIG. 12 is an enlarged view of a portion P of FIG. 11. FIG. 13 is a diagram for explaining a concentration change of a second impurity element along SCAN LINE 3 of FIG. 12.

Referring to FIGS. 11 to 13, in the semiconductor memory device according to some example embodiments, a back gate metal oxide film BGMOX may include a doped second impurity element.

The back gate metal oxide film BGMOX may include a first interface BGMOX_IF1 and a second interface BGMOX_IF2 that are opposite to each other. The first interface BGMOX_IF1 of the back gate metal oxide film may face the back gate insulating film 113. The second interface BGMOX_IF2 of the back gate metal oxide film may face the back gate electrode BG.

At the first interface BGMOX_IF1 of the back gate metal oxide film, the concentration of the second impurity element may be a third impurity concentration. At the second interface BGMOX_IF2 of the back gate metal oxide film, the concentration of the second impurity element may be a fourth impurity concentration that is smaller than the third impurity concentration. The concentration of the second impurity element at the first interface BGMOX_IF1 of the back gate metal oxide film may be greater than the concentration of the second impurity element at the second interface BGMOX_IF2 of the back gate metal oxide film. For example, the concentration of the second impurity element included in the back gate metal oxide film BGMOX may decrease, as it goes away from the back gate insulating film 113.

Because the back gate metal oxide film BGMOX doped with the second impurity element is disposed, it is possible to reduce or prevent the insulating characteristics of the back gate insulating film 113 from being degraded. This makes it possible to improve the performance and/or reliability of the semiconductor memory device.

The second impurity element may include at least one of, for example, niobium (Nb), tantalum (Ta), vanadium (V), zirconium (Zr), aluminum (Al), molybdenum (Mo), cobalt (Co), phosphorus (P), nitrogen (N), or arsenic (As).

As an example, the back gate insulating film 113 may not include the second impurity element. As another example, the back gate insulating film 113 may include the second impurity element.

As an example, the back gate capping metal oxide film CBGMOX may not include the second impurity element. As another example, the back gate capping metal oxide film CBGMOX may include the second impurity element. In such a case, the concentration of the second impurity element in the back gate capping metal oxide film CBGMOX may decrease, as it goes away from the back gate insulating film 113 in the second direction DR2. The concentration of the second impurity element in the back gate metal oxide film BGMOX is greater than the concentration of the second impurity element in the back gate capping metal oxide film CBGMOX.

In FIG. 13, the back gate electrode BG is shown as not including the second impurity element, but example embodiments are not limited thereto. Unlike the shown example, the back gate electrode BG may include the second impurity element at the portion that forms a boundary with the back gate metal oxide film BGMOX.

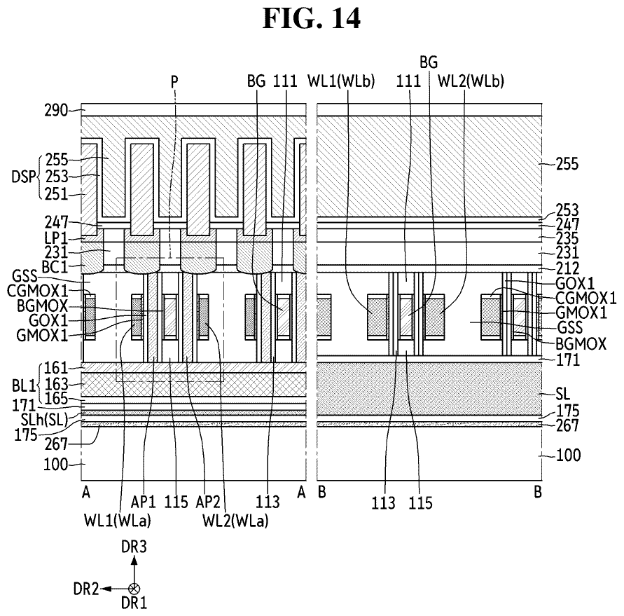

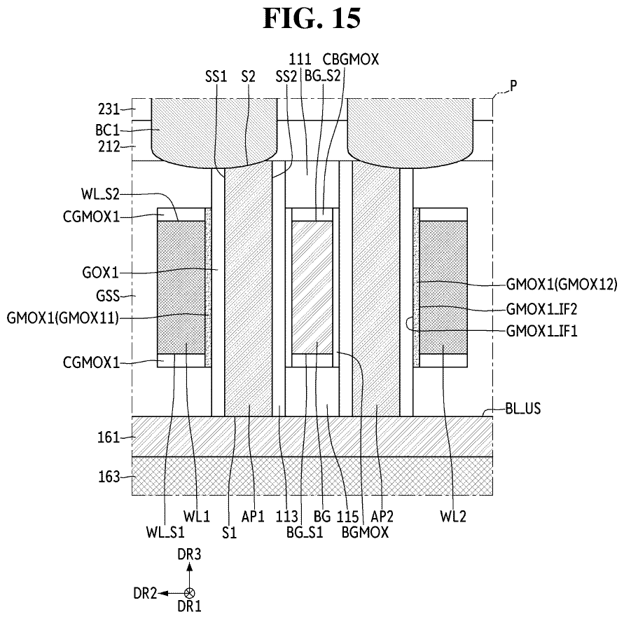

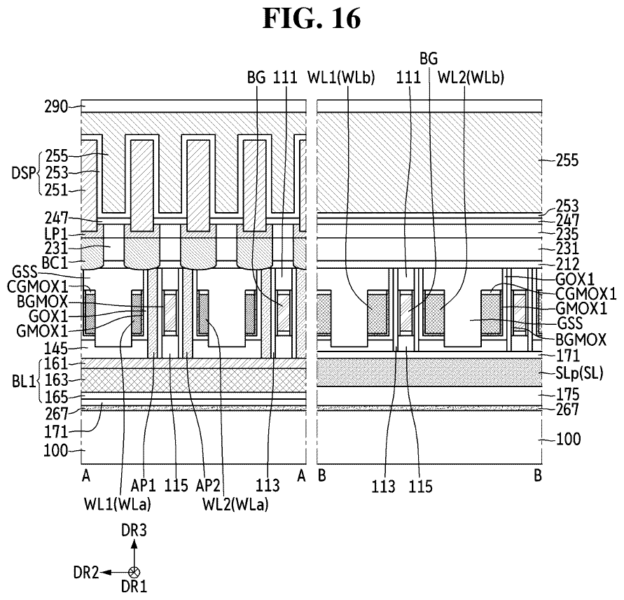

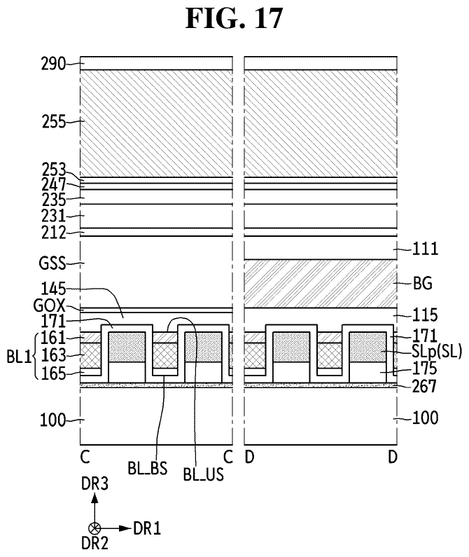

FIGS. 14 and 15 are diagrams for explaining a semiconductor memory device according to some example embodiments. FIGS. 16 and 17 are diagrams for explaining a semiconductor memory device according to some example embodiments. For convenience of explanation, points different from the explanation using FIGS. 1 to 8 will be mainly explained.

Referring to FIGS. 14 and 15, in the semiconductor memory device according to some example embodiments, the first capping gate metal oxide film CGMOX1 may be disposed on the first surfaces WL_S1 of the first and second word lines WL1 and WL2 and the second surfaces WL_S2 of the first and second word lines WL1 and WL2.

The first gate metal oxide film GMOX1 may not extend along the first surfaces WL_S1 of the first and second word lines WL1 and WL2. The first gate metal oxide film GMOX1 may not extend along the second faces WL_S2 of the first and second word lines WL1 and WL2.

The first gate insulating film GOX1 may not extend along the first surfaces WL_S1 of the first and second word lines WL1 and WL2. The first gate insulating film GOX1 may not extend along the second faces WL_S2 of the first and second word lines WL1 and WL2.

The gate separation pattern GSS may cover the first surfaces WL_S1 of the first and second word lines WL1 and WL2. The gate separation pattern GSS may cover the second faces WL_S2 of the first and second word lines WL1 and WL2.

Referring to FIGS. 16 and 17, in the semiconductor memory device according to some example embodiments, the shielding conductive pattern SL may include a plurality of shielding conductive line patterns SLp without a shielding conductive plate SLh.

The shielding conductive pattern SL may not be disposed on the bottom surface BL_BS of the bit line. For example, the shielding insulating capping film 175 may come into contact with the shielding conductive line pattern SLp.

The shielding insulating capping film 175 may have a linear shape extending in the second direction DR2 along the shielding conductive line pattern SLp.

Unlike that shown in the drawings, the shielding insulating capping film 175 may have a flat plate shape. In other words, the shielding insulating capping film 175 may overlap the shielding conductive line pattern SLp and the first bit line BL1 in the third direction DR3.

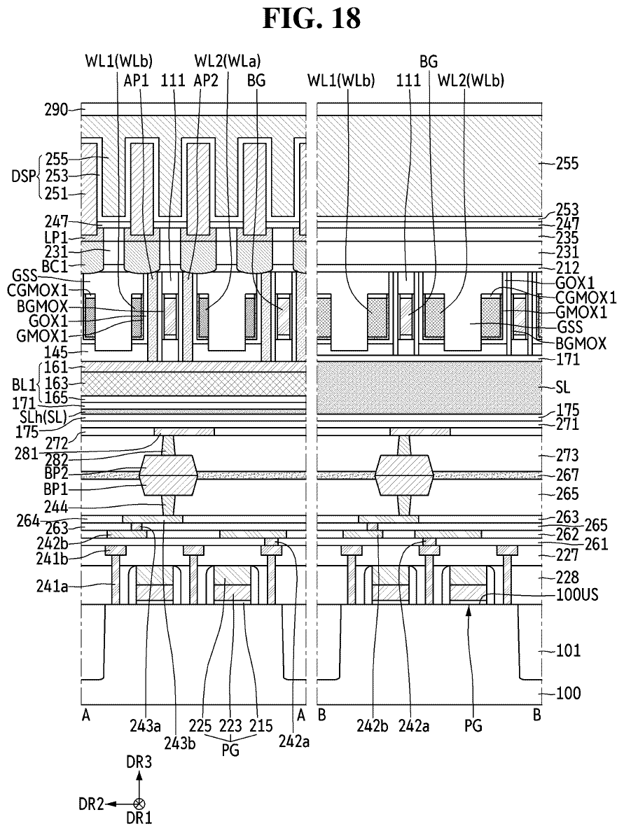

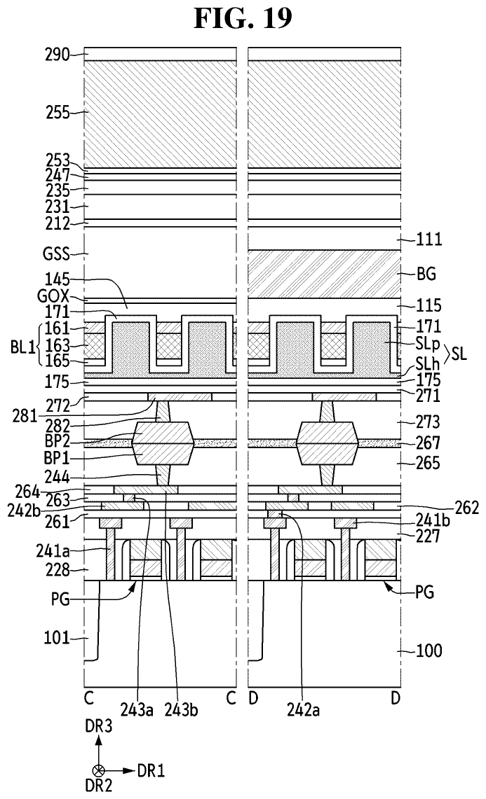

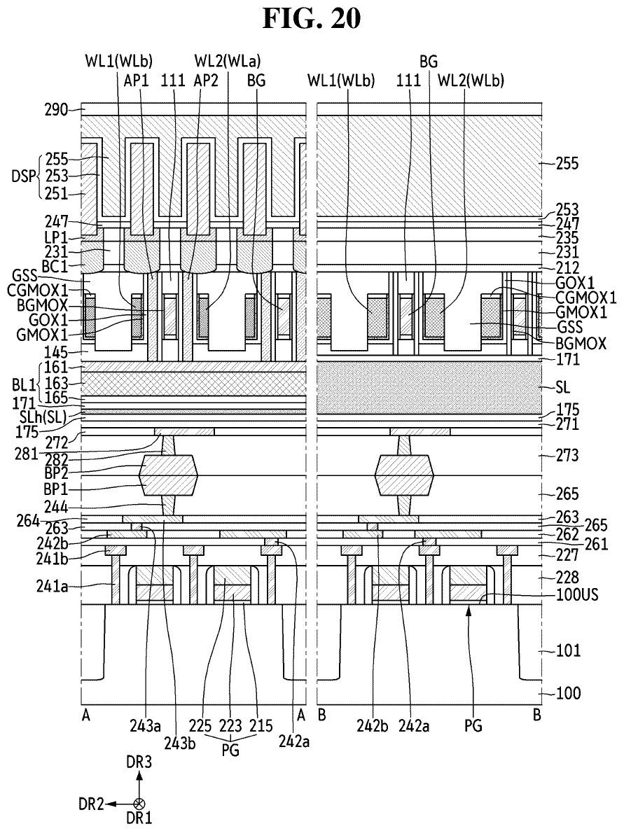

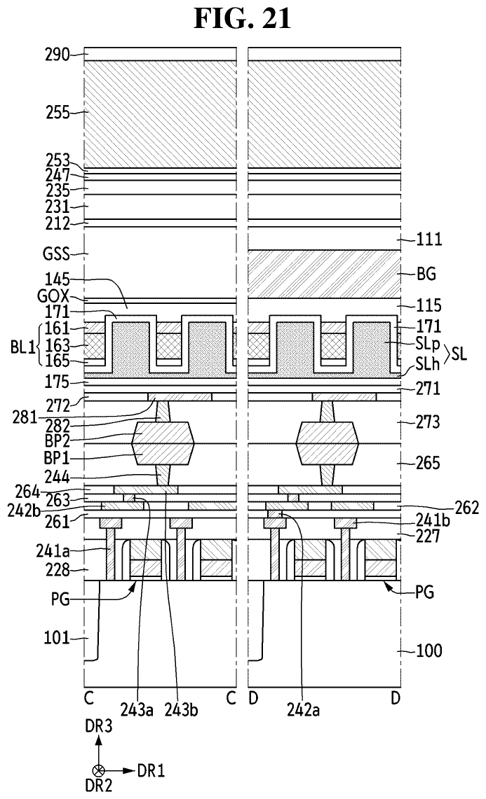

FIGS. 18 and 19 are diagrams for explaining a semiconductor memory device according to some example embodiments. FIGS. 20 and 21 are diagrams for explaining a semiconductor memory device according to some example embodiments. For convenience of explanation, points different from contents explained using FIGS. 1 to 8 will be mainly explained.

For reference, FIGS. 18 and 20 are cross-sectional views taken along A-A and B-B of FIG. 1, respectively. FIGS. 19 and 21 are cross-sectional views taken along C-C and D-D of FIG. 1, respectively.

Referring to FIGS. 18 to 21, the semiconductor memory device according to some example embodiments may further include a peri-gate structure PG disposed between the substrate 100 and the first bit line BL1.

The peri-gate structure PG may be disposed on the substrate 100. For example, the peri-gate structure PG may be disposed on the upper face 100US of the substrate. The peri-gate structure PG may be disposed over the cell array region and the peripheral circuit region. In other words, a part of the peri-gate structure PG may be disposed in the cell array region of the substrate 100, and the remainder of the peri-gate structure PG may be disposed in the peripheral circuit region of the substrate 100.

The peri-gate structure PG may be included in a sensing transistor, a transfer transistor, a driving transistor, or the like. For example, the peri-gate structure PG included in the sensing transistor may be disposed on the cell array region of the substrate 100, but example embodiments are not limited thereto. Needless to say, the type of transistor of the peripheral circuit disposed on the cell array region of the substrate 100 may vary depending on the design placement of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than the silicon oxide film, or a combination thereof. The high dielectric constant insulating film may include, for example, but example embodiments are not limited to, at least one of metal oxide, metal oxynitride, metal silicon oxide, or metal silicon oxynitride.

Each of the peri-lower conductive pattern 223 and the peri-upper conductive pattern 225 include a conductive material. For example, each of the peri-lower conductive pattern 223 and the peri-upper conductive pattern 225 may include at least one of a doped semiconductor material, conductive metal nitride, conductive metal silicon nitride, metal carbonitride, conductive metal silicide, conductive metal oxide, a two-dimensional material (2D material), or metal. The peri-gate structure PG is shown to include a plurality of conductive patterns, but example embodiments are not limited thereto.

Although not shown, the peri-gate structure PG may further include a peri-gate mask pattern disposed on the peri-upper conductive pattern 225. The peri-gate mask pattern is made of an insulating material.

The first peri-lower insulating film 227 and the second peri-lower insulating film 228 are disposed on the upper face 100US of the substrate. Each of the first peri-lower insulating film 227 and the second peri-lower insulating film 228 includes an insulating material.

A peri-contact plug 241a and a peri-wiring line 241b may be disposed inside the first peri-lower insulating film 227 and the second peri-lower insulating film 228. The peri-contact plug 241a and the peri-wiring line 241b may be connected to the conductive patterns 223 and 225 of the peri-gate structure PG. Although not shown, the peri-contact plug 241a and the peri-wiring line 241b may be connected to a source/drain region disposed on at least one side of the peri-gate structure PG.

The peri-contact plug 241a and the peri-wiring line 241b are shown as being different films from each other, but example embodiments are not limited thereto. A boundary between the peri-contact plug 241a and the peri-wiring line 241b may not be distinguished. Each of the peri-contact plug 241a and the peri-wiring line 241b includes a conductive material.

A first peri-upper insulating film 261 and a second peri-upper insulating film 262 may be disposed on the peri-contact plug 241a and the peri-wiring line 241b. Each of the first peri-upper insulating film 261 and the second peri-upper insulating film 262 includes an insulating material. Unlike the shown example, it goes without saying that an insulating film made of a single film may be disposed on the peri-contact plug 241a and the peri-wiring line 241b.

First peri-connecting structures 242a and 242b may be connected to the peri-wiring line 241b. The first peri-connecting structures 242a and 242b may include a first peri-connecting via 242a and a first peri-connecting wiring 242b. The first peri-connecting via 242a and the first peri-connecting wiring 242b each include a conductive material. The first peri-connecting via 242a and the first peri-connecting wiring 242b are shown as being different films from each other, but are not limited thereto.

A third peri-upper insulating film 263 and a fourth peri-upper insulating film 264 may be disposed on the first peri-connecting structures 242a and 242b. Each of the third peri-upper insulating film 263 and the fourth peri-upper insulating film 264 includes an insulating material. It goes without saying that, unlike those shown, an insulating film made of a single film may be disposed on the first peri-connecting structures 242a and 242b.

Second peri-connecting structures 243a and 243b may be connected to the first peri-connecting wiring 242b. The second peri-connecting structure 243a and 243b may include a second peri-connecting via 243a and a second peri-connecting wiring 243b. Each of the second peri-connecting via 243a and the second peri-connecting wiring 243b includes a conductive material. The second peri-connecting via 243a and the second peri-connecting wiring 243b are shown as being different films from each other, but example embodiments are not limited thereto.

The first peri-connecting structures 242a and 242b and the second peri-connecting structures 243a and 243b are shown as being disposed on the peri-gate structure PG, but example embodiments are not limited thereto. It goes without saying that only one peri-connecting structure may be disposed on the peri-gate structure PG, unlike the shown example.

A fifth peri-upper insulating film 265 may be disposed on the second peri-connecting structure 243a and 243b. The fifth peri-upper insulating film 265 includes an insulating material.

A lower bonding pad BP1 may be disposed on the peri-gate structure PG. The lower bonding pad BP1 may be connected to the second peri-connecting structure 243a and 243b.

For example, at least one of the lower bonding pads BP1 may be connected to the peri-gate structure PG. At least the other of the lower bonding pads BP1 may be connected to a source/drain region disposed on at least one side of the peri-gate structure PG.

A lower pad plug 244 may connect the lower bonding pad BP1 and the second peri-connecting wiring 243b. The lower bonding pad BP1 and the lower pad plug 244 may be disposed inside the fifth peri-upper insulating film 265.

A first cell lower insulating film 271, a second cell lower insulating film 272, and a third cell lower insulating film 273 may be disposed on the fifth peri-upper insulating film 265. The first cell lower insulating film 271, the second cell lower insulating film 272, and the third cell lower insulating film 273 may be disposed on the lower bonding pad BP1.

The second cell lower insulating film 272 may be disposed between the first cell lower insulating film 271 and the third cell lower insulating film 273. The first cell lower insulating film 271 may be disposed between the second cell lower insulating film 272 and the fifth peri-upper insulating film 265. Each of the first cell lower insulating film 271, the second cell lower insulating film 272, and the third cell lower insulating film 273 includes an insulating material.

An upper bonding pad BP2 may be disposed on a lower bonding pad BP1. The upper bonding pad BP2 may be disposed on the fifth peri-upper insulating film 265.

The upper bonding pad BP2 may be connected to the lower bonding pad BP1. The upper bonding pad BP2 may come into contact with the lower bonding pad BP1.

A cell connecting wiring 281 may be disposed on the upper bonding pad BP2. The cell connecting wiring 281 may be disposed between the upper bonding pad BP2 and the first bit line BL1. The cell connecting wiring 281 may be disposed between the upper bonding pad BP2 and the shielding conductive pattern SL.

Although not shown, the cell connecting wiring 281 may be connected to at least one of the first bit line BL1 or the shielding conductive pattern SL.

Although the cell connecting wiring 281 disposed at one metal level is shown as being disposed between the upper bonding pad BP2 and the first bit line BL1, this is only for convenience of explanation, and example embodiments are not limited thereto. A plurality of cell connecting wirings 281 disposed at different metal levels from each other may be disposed between the upper bonding pad BP2 and the first bit line BL1.

An upper pad plug 282 may connect the upper bonding pad BP2 and the cell connecting wiring 281. The upper bonding pad BP2 may be connected to the cell connecting wiring 281 through the upper pad plug 282.

The upper bonding pad BP2 and the upper pad plug 282 may be disposed inside the third cell lower insulating film 273. The cell connecting wiring 281 may be disposed inside the second cell lower insulating film 272.

The upper pad plug 282 and the lower pad plug 244 may include a conductive material including metal. The lower bonding pad BP1 and the upper bonding pad BP2 may each include a conductive material including metal. The cell connecting wiring 281 may include a conductive material including metal.

Each of the lower bonding pad BP1 and the upper bonding pad BP2 is shown as being a single film, but this is only for convenience of explanation, and example embodiments are not limited thereto. Each of the upper pad plug 282 and the lower pad plug 244 is shown as being a single film, but example embodiments are not limited thereto. The cell connecting wiring 281 is shown as being a single film, but example embodiments are not limited thereto.

The shielding conductive pattern SL and the first bit line BL1 may be disposed on the peri-gate structure PG. The shielding conductive pattern SL and the first bit line BL1 may be disposed on the upper bonding pad BP2. For example, the shielding conductive pattern SL and the first bit line BL1 may be disposed on the cell connecting wiring 281.

The first cell lower insulating film 271 may be disposed between the first bit line BL1 and the cell connecting wiring 281, and between the shielding conductive pattern SL and the cell connecting wiring 281. The first cell lower insulating film 271 may be disposed between the shielding insulating liner 171 and the second cell lower insulating film 272, and between the shielding insulating capping film 175 and the second cell lower insulating film 272.

The cell upper insulating film 290 may be disposed on the data storage pattern DSP. The cell upper insulating film 290 includes an insulating material.

In FIGS. 18 and 19, the bonding insulating film 267 may be disposed between the third cell lower insulating film 273 and the fifth peri-upper insulating film 265. The bonding insulating film 267 may be disposed between the peri-gate structure PG and the shielding conductive pattern SL.

The bonding insulating film 267 may be disposed along an extension line of the interface between the lower bonding pad BP1 and the upper bonding pad BP2. The interface between the lower bonding pad BP1 and the upper bonding pad BP2 may be the boundary between the lower bonding pad BP1 and the upper bonding pad BP2.

In FIGS. 20 and 21, the bonding insulating film (267 of FIGS. 18 and 19) may not be disposed along an extension line of the interface between the lower bonding pad BP1 and the upper bonding pad BP2. The third cell lower insulating film 273 may come into contact with the fifth peri-upper insulating film 265.

The width of the lower bonding pad BP1 may be equal to the width of the upper bonding pad BP2 at the interface between the lower bonding pad BP1 and the upper bonding pad BP2. Unlike the shown example, the width of the lower bonding pad BP1 may be different from the width of the upper bonding pad BP2 at the interface between the lower bonding pad BP1 and the upper bonding pad BP2.

The lower bonding pad BP1 may be aligned with the upper bonding pad BP2 at the interface between the lower bonding pad BP1 and the upper bonding pad BP2. Unlike the shown example, the lower bonding pad BP1 may be misaligned with the upper bonding pad BP2 at the interface between the lower bonding pad BP1 and the upper bonding pad BP2.

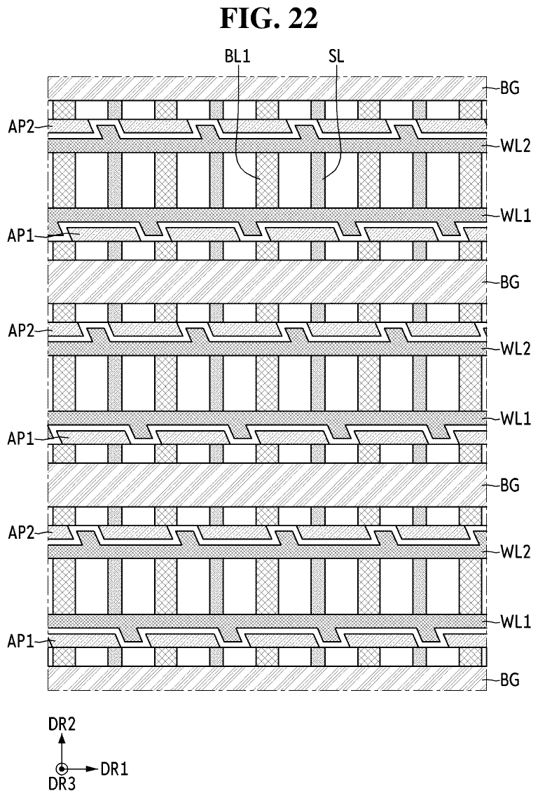

FIGS. 22 to 25 are diagrams for explaining a semiconductor memory device according to some example embodiments. For convenience of explanation, points different from the explanation using FIGS. 1 to 21 will be mainly explained.

Referring to FIG. 22, in the semiconductor memory device according to some example embodiments, the first active pattern AP1 and the second active pattern AP2 may be arranged alternately in a diagonal direction with respect to the first direction DR1 and the second direction DR2. Here, the diagonal direction may be parallel to the upper face of the substrate 100.

Each of the first active pattern AP1 and the second active pattern AP2 may have a parallelogram shape or a rhombus shape from a planar point of view. Because the first active pattern AP1 and the second active pattern AP2 are disposed in the diagonal direction, it is possible to reduce coupling between the first active pattern AP1 and the second active pattern AP2 that face each other in the second direction DR2.

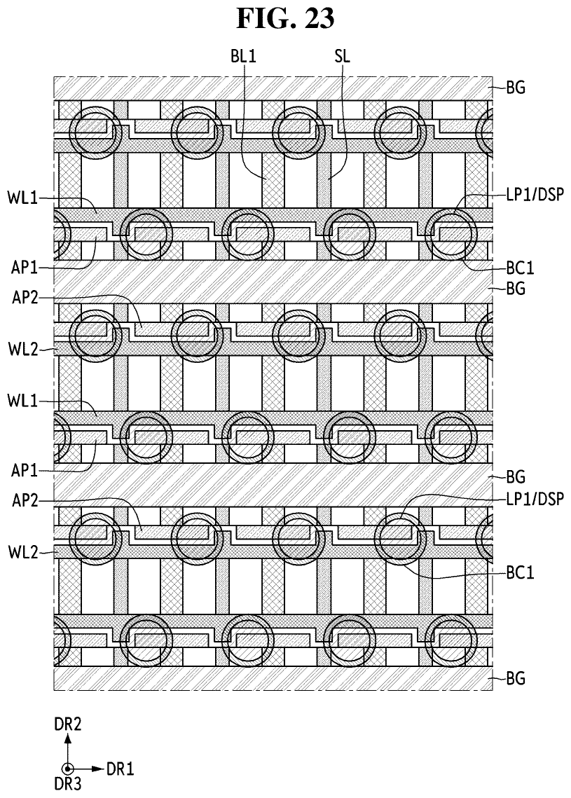

Referring to FIG. 23, in the semiconductor memory device according to some example embodiments, the first landing pads LP1 and the data storage patterns DSP may be arranged in a zigzag shape or a honeycomb shape from a planar point of view.

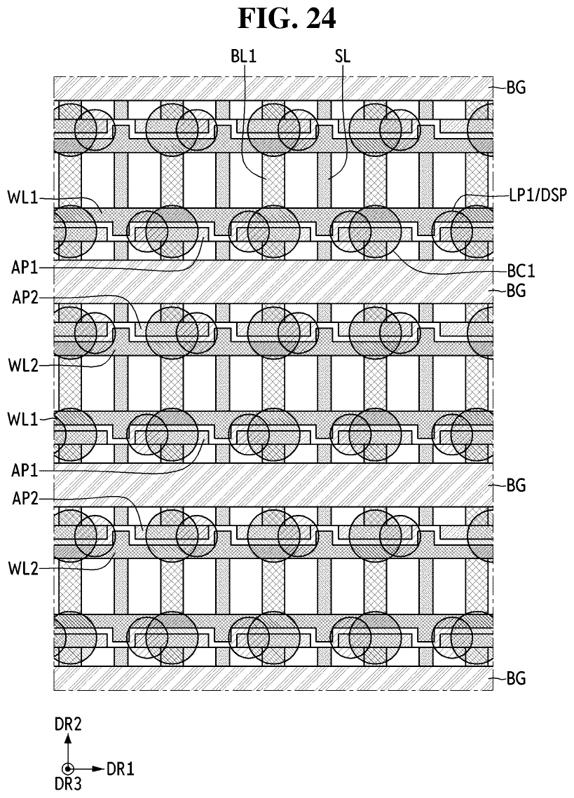

Referring to FIG. 24, in the semiconductor memory device according to some example embodiments, the data storage patterns DSP may be disposed to be offset from the first landing pads LP1 from a planar point of view.

Each data storage pattern DSP may come into contact with a part of the first landing pad LP1.

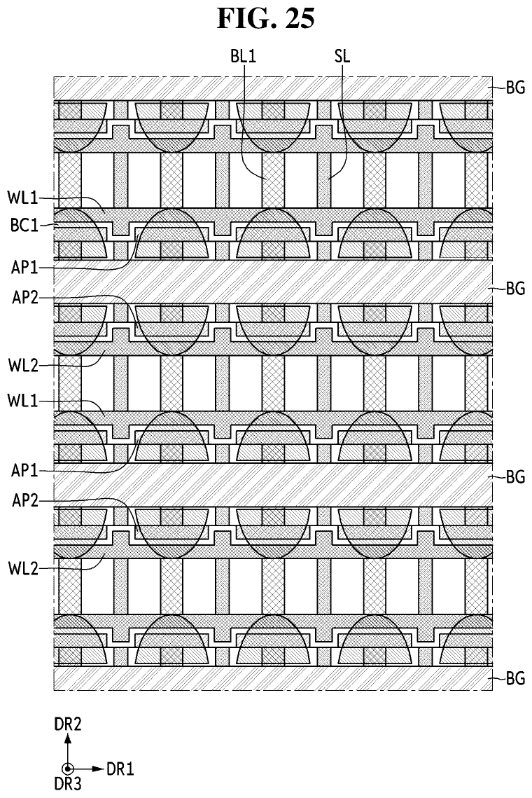

Referring to FIG. 25, in the semiconductor memory device according to some example embodiments, each of the first contact patterns BC1 disposed on the first active pattern AP1 and the second active pattern AP2 may have a semicircular shape or a semi-elliptical shape from a planar point of view.

The first contact patterns BC1 may disposed symmetrically with respect to each other with the back gate electrode interposed between them BG from a planar point of view.

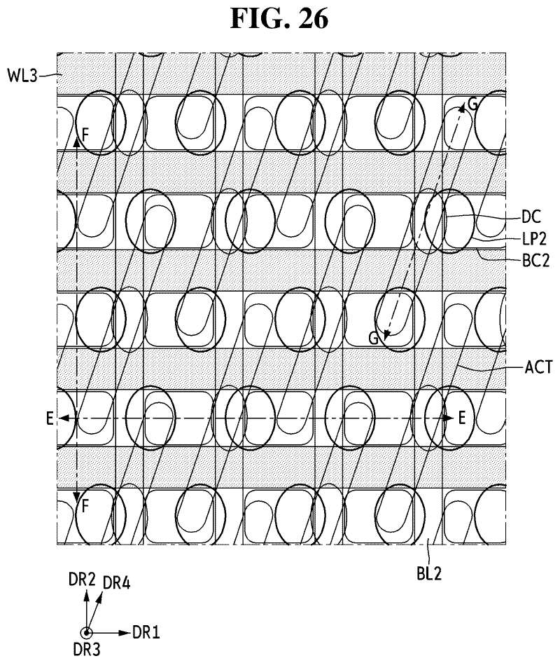

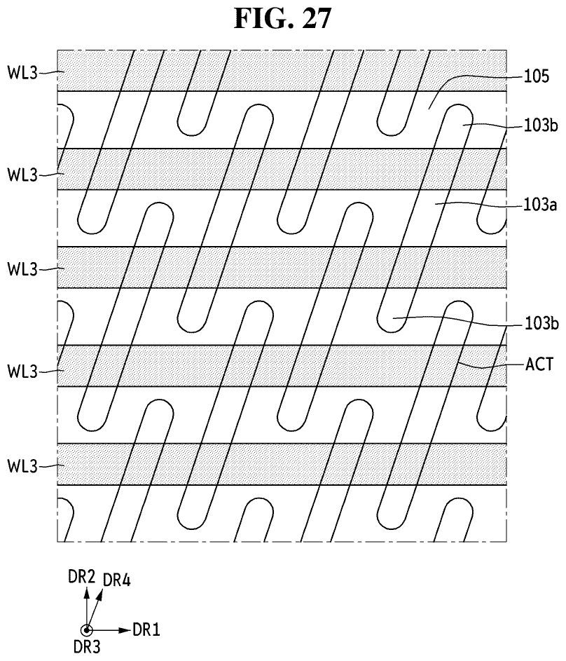

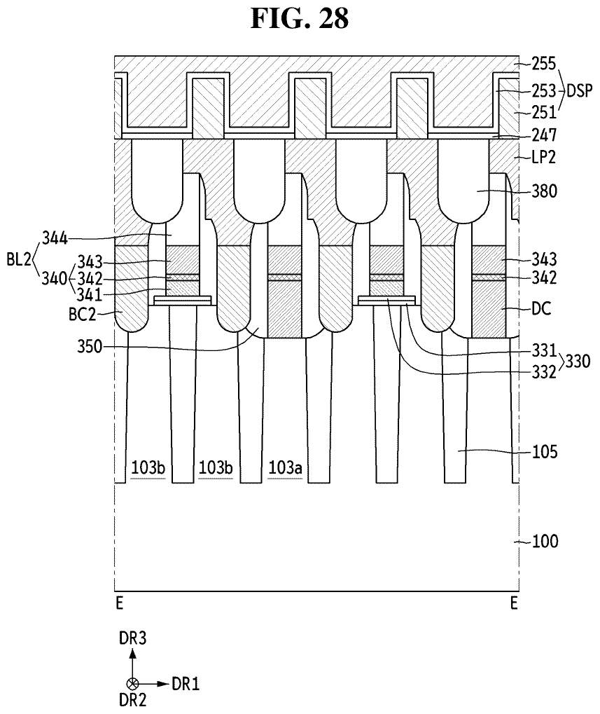

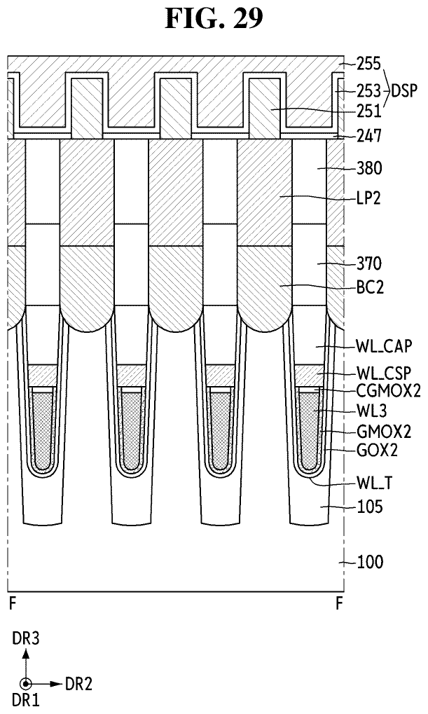

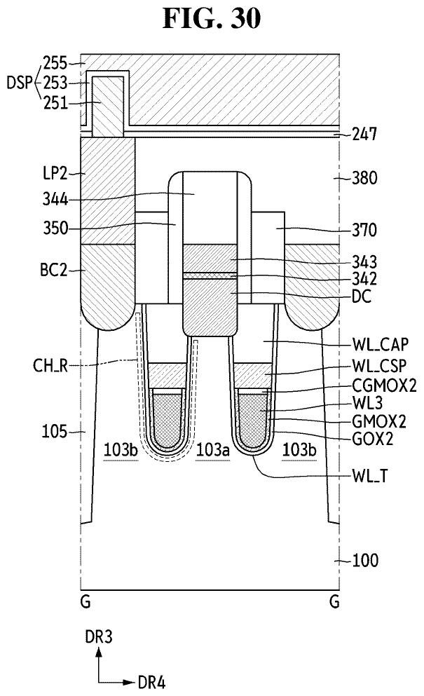

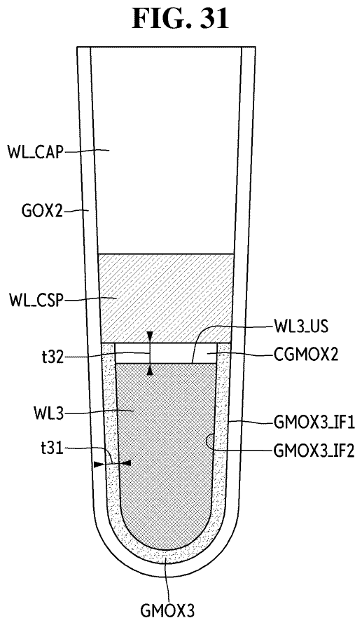

FIG. 26 is a layout diagram for explaining a semiconductor memory device according to some example embodiments. FIG. 27 is a layout showing only the third word line and the cell active region of FIG. 26. FIGS. 28 to 30 are cross-sectional views taken along E-E, F-F, and G-G of FIG. 26. FIG. 31 is an enlarged view for explaining the third word line, the second gate insulating film, the second gate metal oxide film of FIGS. 29 and 30.

The semiconductor memory device according to some example embodiments of the present disclosure may include memory cells including a buried channel array transistor (BCAT).

Referring to FIGS. 26 and 27, the semiconductor memory device according to some example embodiments may include a plurality of cell active regions ACT.

The cell active region ACT may be defined by an element separation film 105 formed inside the substrate (100 of FIG. 28). As the design rule of the semiconductor memory device decreases, the cell active region ACT may be disposed in the form of bar of a diagonal line or oblique line, as shown. For example, the cell active region ACT may extend in a fourth direction DR4.

A plurality of gate electrodes extending in the first direction DR1 across the cell active region ACT may be disposed. The plurality of gate electrodes may extend to be parallel to each other. The plurality of gate electrodes may be, for example, a plurality of third word lines WL3. The third word lines WL3 may be disposed at equal intervals. The width of the third word lines WL3 and the interval between the third word lines WL3 may be determined depending on the design rule.

A plurality of second bit lines BL2 extending in the second direction DR2 perpendicular to the third word line WL3 may be disposed on the third word line WL3. The plurality of second bit lines BL may extend to be parallel to each other. The second bit lines BL2 may be disposed at equal intervals. The width of the second bit lines BL2 and the interval between the second bit lines BL2 may be determined depending on a design rule.

The two third word lines WL3 extending in the first direction DR1 may divide each cell active region ACT into three portions. The cell active region ACT may include a first portion 103a, and a second portion 103b defined on both sides of the first portion 103a. The first portion 103a of the cell active region ACT may be located at a center portion of the cell active region ACT, and the second portion 103b of the cell active region ACT may be located at an end portion of the cell active region ACT. For example, the first portion 103a of the cell active region ACT may be a region connected to the second bit line BL2, and the second portion 103b of the cell active region ACT may be a region connected to the data storage pattern (DSP of FIG. 28). In other words, a common drain region may be located in the first portion 103a of the cell active region ACT, and a source region may be located in the second portion 103b of the cell active region ACT.

The fourth direction DR4 may be perpendicular to the third direction DR3. The fourth direction DR4 may be placed on the same plane as the first direction DR1 and the second direction DR2.

The semiconductor memory device according to some example embodiments may include various contact arrangements formed on the cell active region ACT. The various contact arrangements may include, for example, a direct contact (DC), a second contact pattern BC2, and a second landing pad LP2.

Here, the direct contact DC may mean a contact that electrically connects the cell active region ACT to the second bit line BL2. The second contact pattern BC2 may mean a contact that connects the cell active region ACT to the storage electrode (251 of FIG. 29) of the data storage pattern DSP. In terms of the arrangement structure, the contact area between the second contact pattern BC2 and the cell active region ACT may be small. Therefore, a conductive second landing pad LP2 may be introduced to enlarge the contact area with the cell active region ACT and enlarge the contact area with the storage electrode (251 of FIG. 28).

The second landing pad LP2 may be disposed between the cell active region ACT and the second contact pattern BC2, or may be disposed between the second contact pattern BC2 and the storage electrode (251 of FIG. 28). In the semiconductor memory device according to some example embodiments, the second landing pad LP2 may be disposed between the second contact pattern BC2 and the storage electrode (251 of FIG. 28). By enlarging the contact area through the introduction of the second landing pad LP2, the contact resistance between the cell active region ACT and the storage electrode (251 of FIG. 28) may be reduced.

The direct contact DC may be disposed in the center portion of the cell active region ACT. The direct contact DC may be connected to the first portion 103a of the cell active region ACT. The second contact pattern BC2 may be disposed at both end portions of the cell active region ACT. The second contact pattern BC2 may be connected to the second portion 103b of the cell active region ACT.

As the second contact pattern BC2 is disposed at both end portions of the cell active region ACT, the second landing pad LP2 may be disposed to be adjacent to both ends of the cell active region ACT to partially overlap the second contact pattern BC2. In other words, the second contact pattern BC2 may be formed to overlap the cell active region ACT and the element separation film 105 between the adjacent third word lines WL3 and between the adjacent second bit lines BL2.

The third word line WL3 may be formed as a structure buried in the substrate 100. The third word line WL3 may be disposed across the cell active region ACT between the direct contact DC and the second contact pattern BC2. As shown, two third word lines WL3 may be disposed to cross one cell active region ACT. Since the cell active region ACT extends along the fourth direction DR4, the third word line WL3 may have an angle of less than 90 degrees with the cell active region ACT.

The direct contact DC and the second contact pattern BC2 may be disposed symmetrically. As a result, the direct contact DC and the second contact pattern BC2 may be disposed on a straight line along the first direction DR1 and the second direction DR2.

On the other hand, unlike the direct contact DC and the second contact pattern BC2, the second landing pad LP2 may be disposed in a zigzag pattern in the second direction DR2 in which the second bit line BL2 extends. Also, the second landing pads LP2 may be disposed to overlap the same side face portions of each second bit line BL2 in the first direction DR1 in which the third word line WL3 extends.

For example, each of the second landing pads LP2 of the first line may overlap the left side of the corresponding second bit line BL2, and each of the second landing pads LP2 of the second line may overlap the right side of the corresponding second bit line BL2.

Referring to FIGS. 26 to 31, the semiconductor memory device according to some example embodiments may include a third word line WL3, a third gate metal oxide film GMOX3, a second capping gate metal oxide film CGMOX2, a second bit line BL2, a direct contact DC, a second contact pattern BC2, and a data storage pattern DSP.

The element separation film 105 may be disposed inside the substrate 100. The element separation film 105 may have a shallow trench isolation (STI) structure having excellent element separation characteristics. The cell active region ACT defined by the element separation film 105 may have a long island formation including a short axis and a long axis, as shown in FIGS. 26 and 27. The cell active region ACT may have an oblique line shape to have an angle of less than 90 degrees with respect to the third word line WL3 formed inside the element separation film 105. The cell active region ACT may also have an oblique line shape to have an angle of less than 90 degrees with respect to the second bit line BL2 formed on the element separation film 105. The element separation film 105 may include an insulating material.

The substrate 100 may include a cell gate trench WL_T. The cell gate trench WL_T may be disposed inside the substrate 100 and the element separation film 105. The cell gate trench WL_T may be disposed across the cell active region ACT.

The second gate insulating film GOX2, the third gate metal oxide film GMOX3, the second capping gate metal oxide film CGMOX2, the third word line WL3, the gate capping conductive film WL_CSP, and the gate capping film WL_CAP may be disposed inside the cell gate trench WL_T.

In FIG. 30, the substrate 100 may include a buried channel region CH_R defined along the profile of the cell gate trench WL_T. The first portion 103a of the cell active region ACT, the second portion 103b of the cell active region ACT, and the third word line WL3 may constitute a buried channel transistor. The buried channel region CH_R may be a channel region of the buried channel transistor.

The third word line WL3 may extend in the first direction DR1 inside the cell gate trench WL_T. The third word line WL3 may include a conductive material. The third word line WL3 may include at least one of, for example, a conductive semiconductor material, conductive metal nitride, conductive metal silicon nitride, metal carbonitride, conductive metal silicide, a two-dimensional material, or metal.

In the semiconductor memory device according to some example embodiments, the third word line WL3 may include a third metal element. For example, the third metal element may be titanium (Ti). The third word line WL3 may include titanium nitride (TiN).

The second gate insulating film GOX2 may be disposed between the substrate 100 and the third word line WL3. For example, the second gate insulating film GOX2 may be disposed between the buried channel region CH_R and the third word line WL3.

The second gate insulating film GOX2 may extend along a profile of the cell gate trench WL_T. The second gate insulating film GOX2 may be formed of an insulating material. The second gate insulating film GOX2 may include, for example, but example embodiments are not limited to, silicon oxide.

The third gate metal oxide film GMOX3 may be disposed between the third word line WL3 and the buried channel region CH_R. The third gate metal oxide film GMOX3 may be disposed between the third word line WL3 and the second gate insulating film GOX2.

The third gate metal oxide film GMOX3 may extend along the boundary between the third word line WL3 and the second gate insulating film GOX2. In the semiconductor memory device according to some example embodiments, the third gate metal oxide film GMOX3 may come into contact with the third word line WL3.

The second capping gate metal oxide film CGMOX2 may be disposed on the upper surface WL3_US of the third word line. The second capping gate metal oxide film CGMOX2 may come into contact with the third word line WL3.

For example, the third gate metal oxide film GMOX3 and the second capping gate metal oxide film CGMOX2 may include third metal oxide. The third metal oxide may be oxide of a third metal element included in the third word line WL3. When the third word line WL3 includes titanium nitride (TiN), the third metal oxide may be titanium oxide. The third gate metal oxide film GMOX3 and the second capping gate metal oxide film CGMOX2 may include titanium oxide.

A thickness t32 of the second capping gate metal oxide film CGMOX2 is different from a thickness t31 of the third gate metal oxide film GMOX3. For example, the thickness t32 of the second capping gate metal oxide film CGMOX2 may be greater than the thickness t31 of the third gate metal oxide film GMOX3.

The third gate metal oxide film GMOX3 may include a doped first impurity element. The first impurity element may include, for example, at least one of niobium (Nb), tantalum (Ta), vanadium (V), zirconium (Zr), aluminum (Al), molybdenum (Mo), cobalt (Co), phosphorus (P), nitrogen (N), or arsenic (As).

The third gate metal oxide film GMOX3 may include a first interface GMOX3_IF1 and a second interface GMOX3_IF2 that are opposite to each other. The first interface GMOX3_IF1 of the third gate metal oxide film may face the second gate insulating film GOX2. The second interface GMOX3_IF2 of the third gate metal oxide film may face the third word line WL3.

The concentration of the first impurity element may be a fifth impurity concentration at the first interface GMOX3_IF1 of the third gate metal oxide film. The concentration of the first impurity element may be a sixth impurity concentration that is smaller than the fifth impurity concentration at the second interface GMOX3_IF2 of the third gate metal oxide film. The concentration of the first impurity element at the first interface GMOX3_IF1 of the third gate metal oxide film may be greater than the concentration of the first impurity element at the second interface GMOX3_IF2 of the third gate metal oxide film. For example, the concentration of the first impurity element included in the third gate metal oxide film GMOX3 may decrease, as it goes away from the second gate insulating film GOX2.

As an example, the second gate insulating film GOX2 may not include the first impurity element. As another example, the second gate insulating film GOX2 may include the first impurity element.

As an example, the second capping gate metal oxide film CGMOX2 may not include the first impurity element. As another example, the second capping gate metal oxide film CGMOX2 may include the first impurity element. In such a case, the concentration of the first impurity element in the second capping gate metal oxide film CGMOX2 may decrease, as it goes away from the second gate insulating film GOX2 in the second direction DR2. The concentration of the first impurity element in the third gate metal oxide film GMOX3 is greater than the concentration of the first impurity element in the second capping gate metal oxide film CGMOX2.

As an example, the third word line WL3 may not include the first impurity element. As another example, the third word line WL3 may include a first impurity element at a portion that forms a boundary with the third gate metal oxide film GMOX3.

The gate capping conductive film WL_CSP may be disposed on the second capping gate metal oxide film CGMOX2. The gate capping conductive film WL_CSP may extend along the upper surface WL3_US of the third word line. The gate capping conductive film WL_CSP may include, but example embodiments are not limited to, polysilicon or polysilicon-germanium.

The gate capping film WL_CAP may be disposed on the gate capping conductive film WL_CSP. The gate capping film WL_CAP may be disposed inside the cell gate trench WL_T. The gate capping film WL_CAP may include, but example embodiments are not limited to, silicon nitride.

The second bit line BL2 may include a cell conductive line 340 and a bit line capping film 344.

The cell conductive line 340 may be disposed on the substrate 100 and the element separation film 105 on which the third word line WL3 is formed. The cell conductive line 340 may intersect the element separation film 105 and the cell active region ACT defined by the element separation film 105. The cell conductive line 340 may be disposed to intersect the third word line WL3.

The cell conductive line 340 may include, for example, at least one of a semiconductor material doped with impurities, a conductive silicide compound, conductive metal nitride, a two-dimensional (2D) material, metal, or a metal alloy.

The cell conductive line 340 may be a single film or a double film, but may also be a multi-film including a first conductive line 341, a second conductive line 342, and a third conductive line 343 as shown. The cell conductive line 340 is shown as a triple film, but example embodiments are not limited thereto. That is, the cell conductive line 340 may include either a single film or a plurality of conductive films in which conductive materials are stacked.

The bit line capping film 344 may be disposed on the cell conductive line 340. The bit line capping film 344 may extend in the second direction DR2 along the upper face of the cell conductive line 340. The bit line capping film 344 may include, for example, at least one of a silicon nitride film, silicon oxynitride, silicon carbonitride, or silicon oxycarbonitride.

In the semiconductor memory device according to some example embodiments, the bit line capping film 344 may include a silicon nitride film. The bit line capping film 344 is shown as being a single film, but example embodiments are not limited thereto.

The direct contact DC may be disposed between the cell conductive line 340 and the substrate 100. That is, the cell conductive line 340 may be disposed on the direct contact DC. For example, the direct contact DC may be formed at a point where the cell conductive line 340 intersects a central portion of the cell active region ACT having a long island shape. The direct contact DC may be disposed between the first portion 103a of the cell active region ACT and the cell conductive line 340. The direct contact DC may electrically connect the cell conductive line 340 and the substrate 100. The direct contact DC may include, for example, at least one of an impurity-doped semiconductor material, a conductive silicide compound, conductive metal nitride, or metal.

The bit line insulating film 330 may be disposed on the substrate 100 and the element separation film 105. For example, the bit line insulating film 330 may be disposed on the upper face of the substrate 100 and the element separation film 105 on which the direct contact DC and the second contact pattern BC2 are not formed. The bit line insulating film 330 may be disposed between the substrate 100 and the cell conductive line 340, and between the element separation film 105 and the cell conductive line 340.

Although the bit line insulating film 330 may be a single film, as shown, the cell insulating film 330 may be a multi-film including a first cell insulating film 331 and a second cell insulating film 332. For example, the first cell insulating film 331 may include a silicon oxide film, and the second cell insulating film 332 may include a silicon nitride film, but example embodiments are not limited thereto. Unlike the shown example, the cell insulating film 330 may be, but example embodiments are not limited to, a triple film including a silicon oxide film, a silicon nitride film, and a silicon oxide film.

A bit line spacer 350 may be disposed on the side wall of the second bit line BL2. The bit line spacer 350 may be disposed on the side wall of the cell conductive line 340 and the side wall of the bit line capping film 344. In the portion of the cell conductive line 340 in which the direct contact DC is formed, the bit line spacer 350 may be disposed on the substrate 100 and the element separation film 105. The bit line spacer 350 may be disposed on the side wall of the cell conductive line 340, the side wall of the bit line capping film 344, and the side wall of the direct contact DC. In the remaining portion of the cell conductive line 340 in which the direct contact DC is not formed, the bit line spacer 350 may be disposed on the bit line insulating film 330. The bit line spacer 350 may be disposed on the side wall of the cell conductive line 340 and the side wall of the bit line capping film 344.

Although the bit line spacer 350 is shown as being a single film, this is only for convenience of explanation, and the embodiment is not limited thereto. In other words, unlike the shown example, it goes without saying that the bit line spacer 350 may have a multi-film structure. The bit line spacer 350 may include, for example, but example embodiments are not limited to, a silicon oxide film, a silicon nitride film, a silicon oxynitride film (SiON), a silicon oxycarbonitride film (SiOCN), air, and combinations thereof.

A fence pattern 370 may be disposed on the substrate 100 and the element separation film 105. The fence pattern 370 may be disposed to overlap a third word line WL3 formed in the substrate 100 and the element separation film 105.

The fence pattern 370 may be disposed between the second bit lines BL2 extending in the second direction DR2. The fence pattern 370 may include, for example, at least one of silicon oxide, silicon nitride, silicon oxynitride, or combinations thereof.

A second contact pattern BC2 may be disposed between the cell conductive lines 340 adjacent to each other in the first direction DR1. The second contact pattern BC2 may be disposed on both sides of the cell conductive line 340. More specifically, the second contact pattern BC2 may be disposed between the second bit lines BL2. The second contact pattern BC2 may be disposed between the fence patterns 370 adjacent to each other in the second direction DR2.

The second contact pattern BC2 may overlap the substrate 100 and the element separation film 105 between the adjacent cell conductive lines 340. The second contact pattern BC2 may be connected to the cell active region ACT.

The second contact pattern BC2 may include, for example, at least one of a semiconductor material doped with an impurity, a conductive silicide compound, conductive metal nitride, or metal.

A second landing pad LP2 may be disposed on the second contact pattern BL2. The second landing pad LP2 may be electrically connected to the second contact pattern BL2. The second landing pad LP2 may be connected to the second portion 103b of the active region ACT.

The second landing pad LP2 may overlap a part of the upper face of the second bit line BL2. The second landing pad LP2 may include, for example, at least one of conductive metal nitride, conductive metal carbide, metal, or metal alloy.

A pad separation insulating film 380 may be disposed on the second landing pad LP2 and the second bit line BL2. For example, the pad separation insulating film 180 may be disposed on the bit line capping film 344. The pad separation insulating film 380 may define the second landing pad LP2 that forms a plurality of isolation regions. The pad separation insulating film 380 may not cover the upper face of the second landing pad LP2.

The pad separation insulating film 380 may include an insulating material, and may electrically separate the plurality of second landing pads LP2 from each other. For example, the pad separation insulating film 380 may include, for example, at least one of a silicon oxide film, a silicon nitride film, a silicon oxynitride film, a silicon oxycarbonitride film, or a silicon carbonitride film.

The data storage pattern DSP may be disposed on the second landing pad LP2.

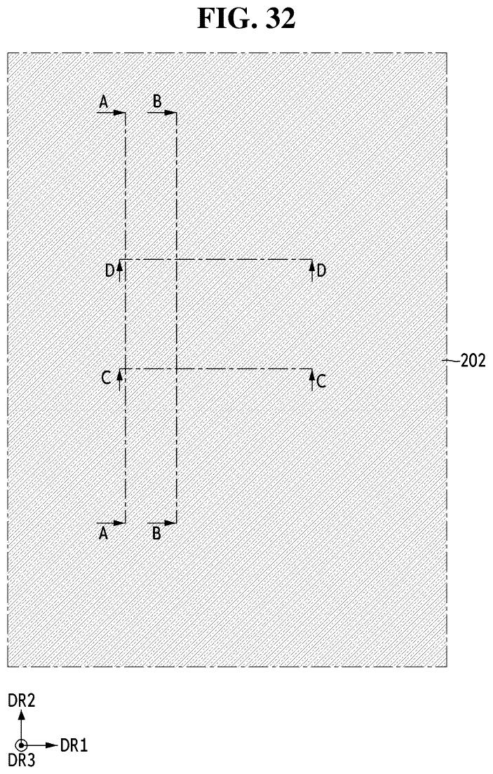

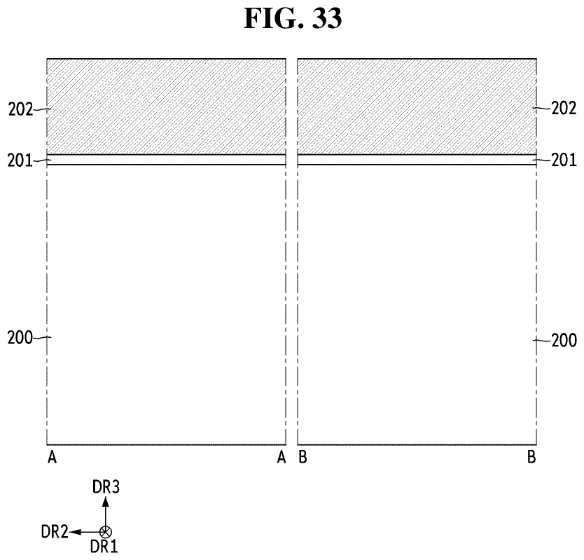

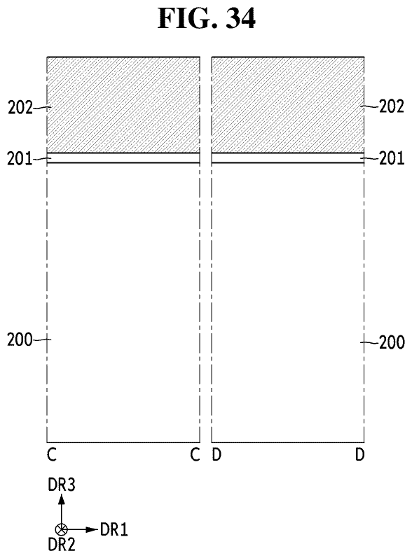

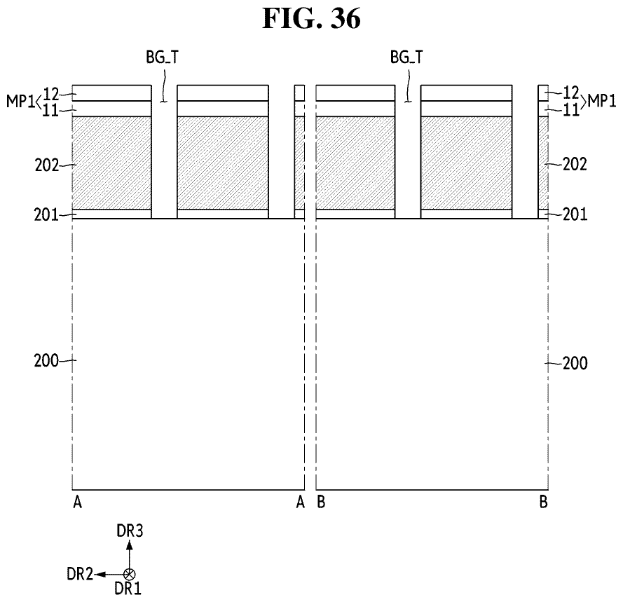

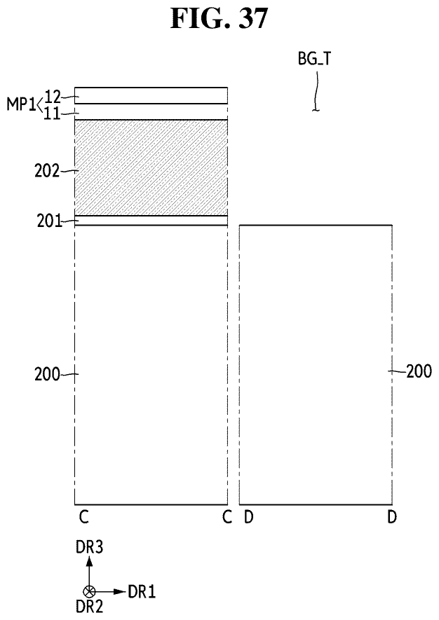

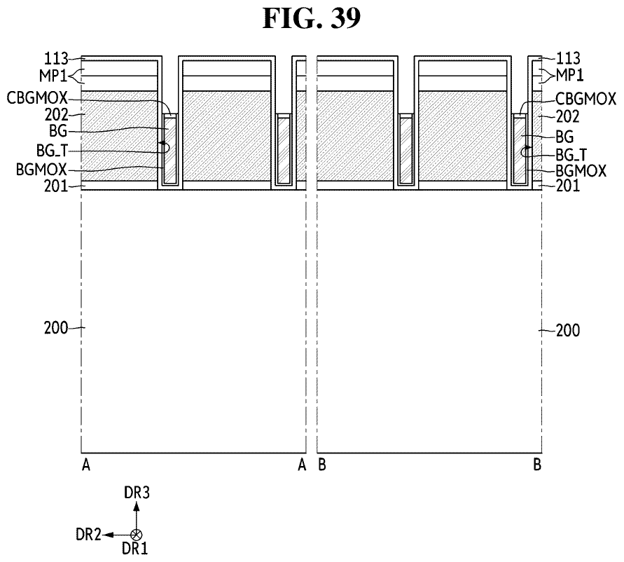

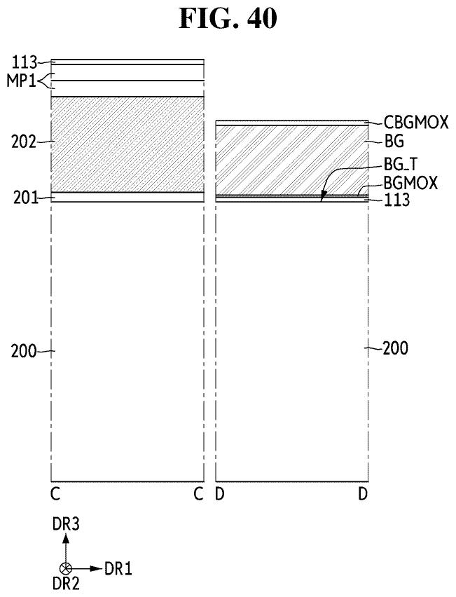

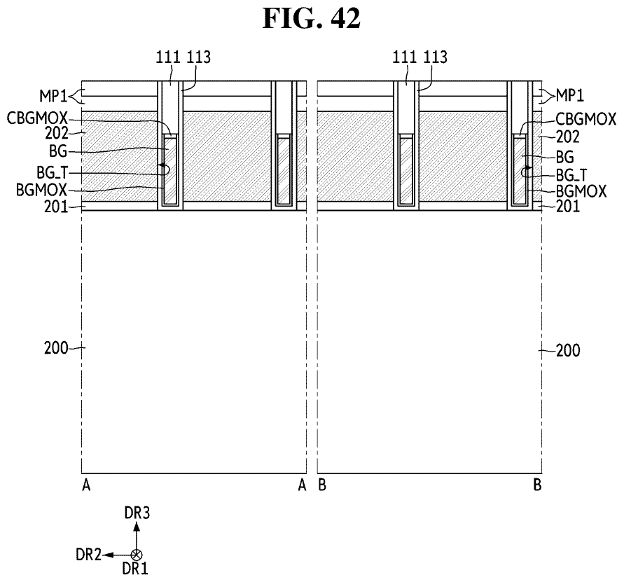

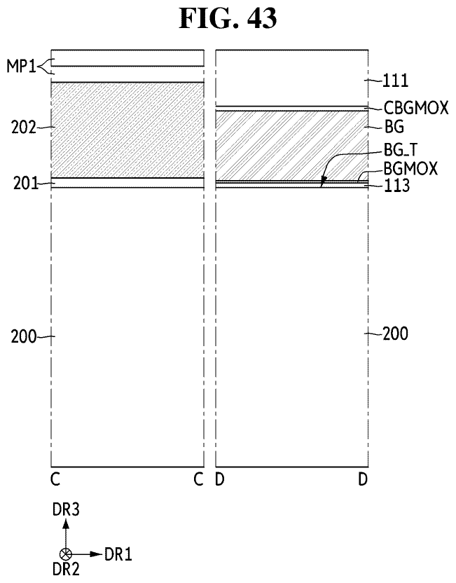

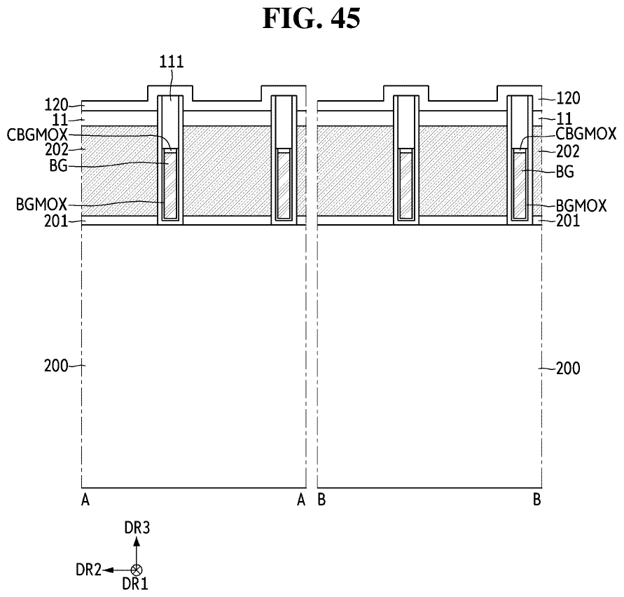

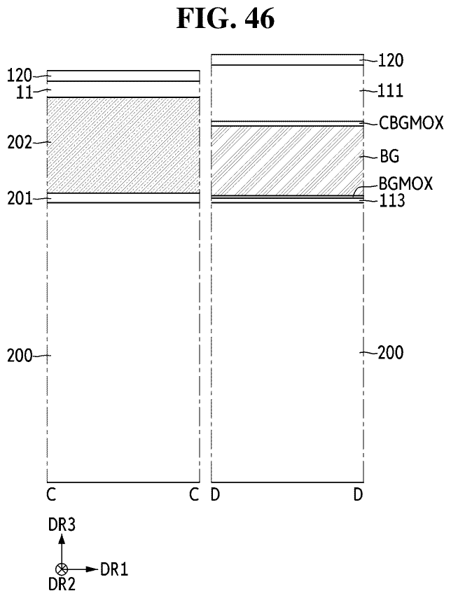

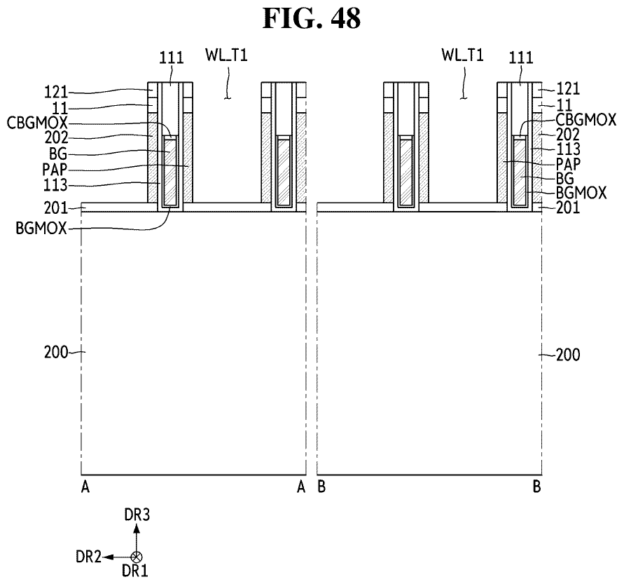

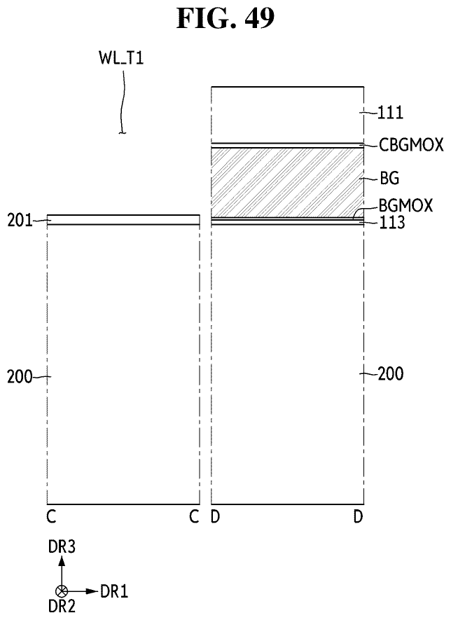

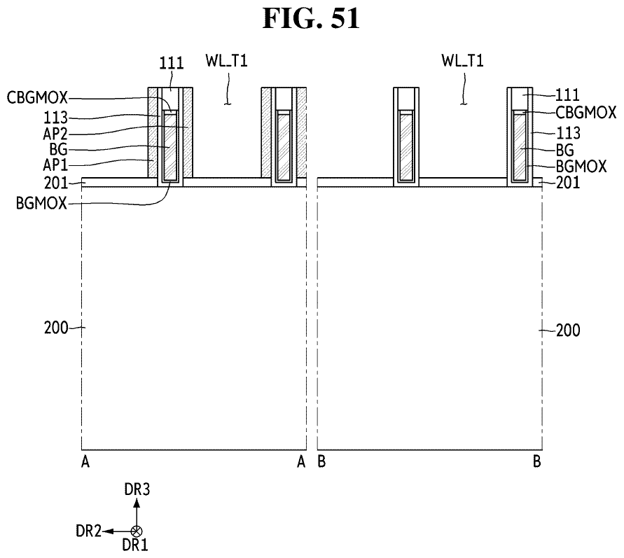

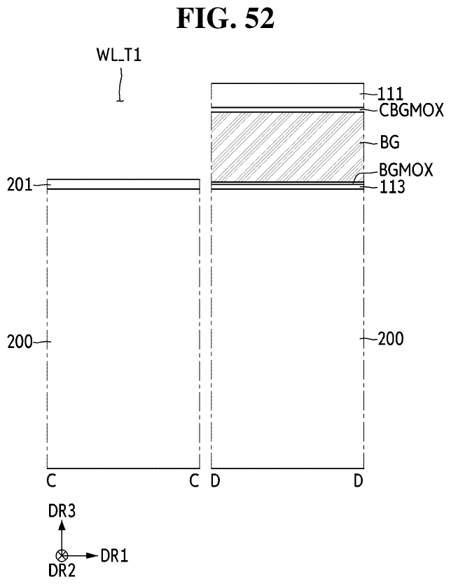

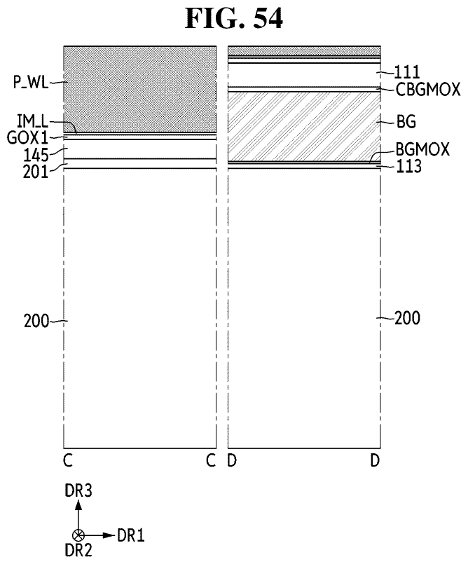

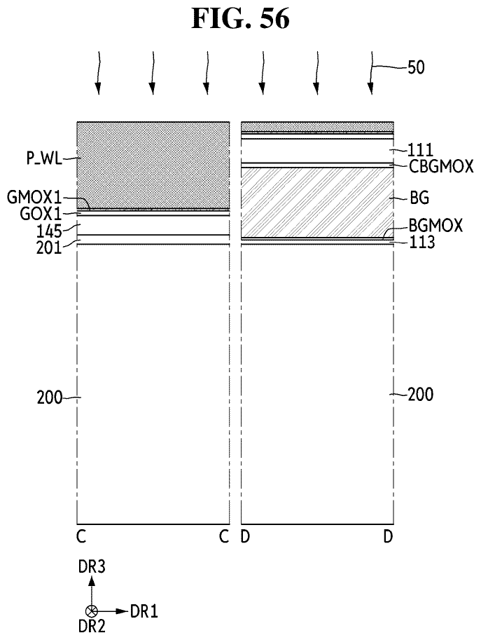

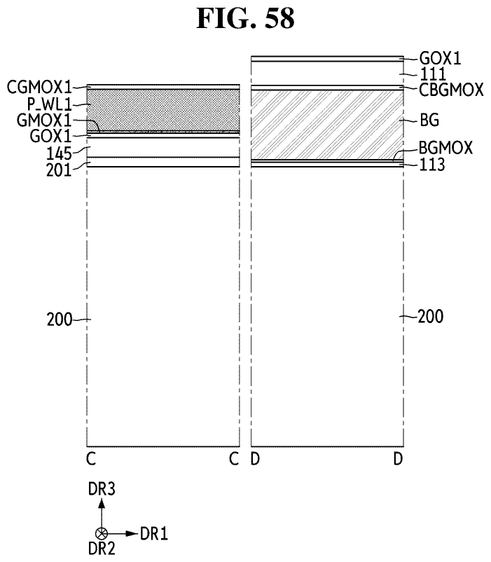

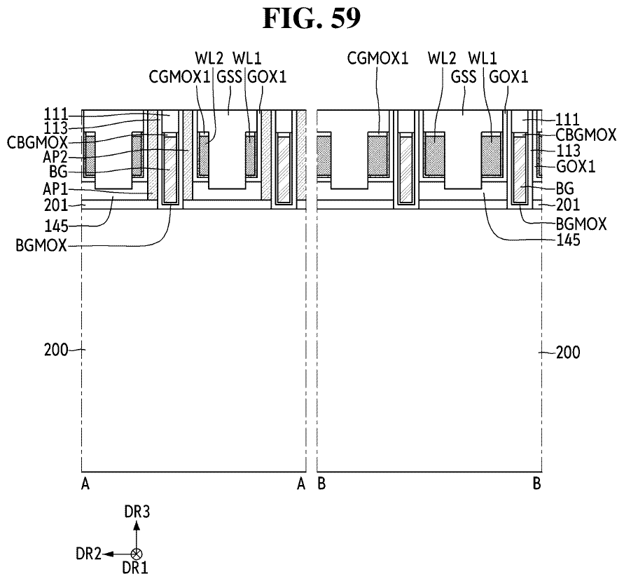

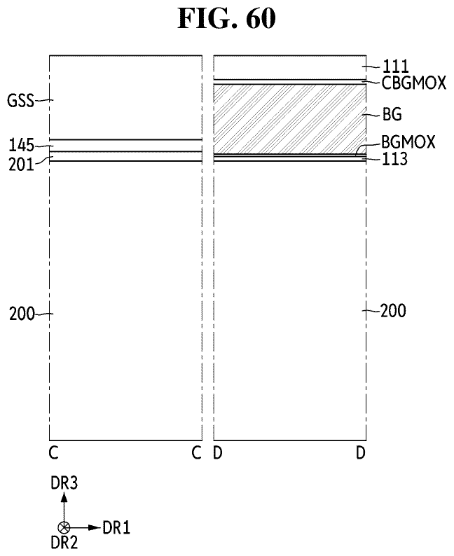

FIGS. 32 to 64 are intermediate stage diagrams for explaining a method for fabricating a semiconductor memory device according to some example embodiments. Accordingly, the semiconductor memory device explained using to FIGS. 18 and 19 may be fabricated.

Referring to FIGS. 32 to 34, a sub-substrate structure including a first sub-substrate 200, a buried insulating layer 201, and an active layer 202 may be provided.

The buried insulating layer 201 and the active layer 202 may be provided on the first sub-substrate 200. The first sub-substrate 200, the buried insulating layer 201, and the active layer 202 may be a silicon-on-insulator substrate (i.e., an SOI substrate). The first sub-substrate 200 may be a semiconductor substrate. The first sub-substrate 200 may be, for example, a silicon substrate, a germanium substrate, and/or a silicon-germanium substrate. In the following description, the first sub-substrate 200 will be described as being a silicon substrate.

The buried insulating layer 201 may be a buried oxide (BOX) formed by a separation by implanted oxygen method (SIMOX) or a bonding and layer transfer method. In contrast, the buried insulating layer 201 may be an insulating film formed by a chemical vapor deposition. The buried insulating layer 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a single crystal silicon substrate, a germanium substrate, and/or a silicon-germanium substrate. The active layer 202 may have a first face and a second face that are opposite to each other in the third direction D3, and the second face of the active layer 202 may be in contact with the buried insulating layer 201.

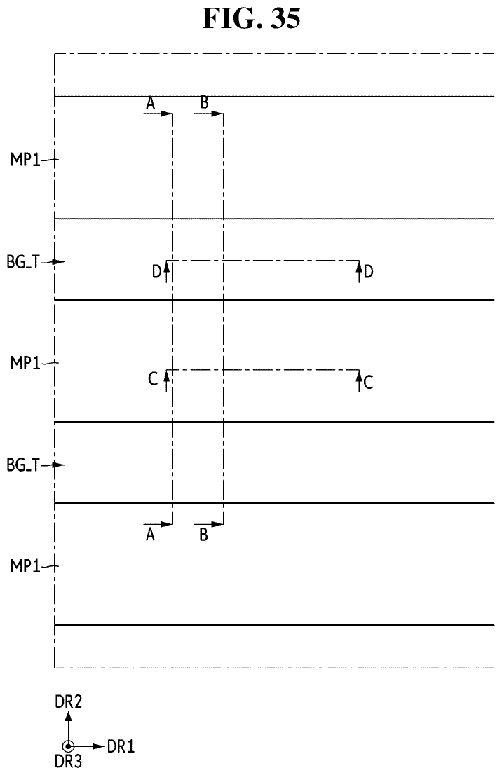

Referring to FIGS. 35 to 37, a mask pattern MP1 may be formed on the active layer 202.

The mask pattern MP1 may have linear openings extending along the first direction D1. The mask pattern MP1 may include a first lower mask film 11 and a first upper mask film 12 that are stacked in sequence. The first upper mask film 12 may be made of a material that has etching selectivity with respect to the first lower mask film 11. As an example, the first lower mask film 11 may include silicon oxide, and the first upper mask film 12 may include silicon nitride, but example embodiments are not limited thereto.

Subsequently, the active layer 202 may be anisotropically etched, by using the mask pattern MP1 as an etching mask. Accordingly, the back gate trenches BG_T extending in the first direction D1 may be formed on the active layer 202. The back gate trenches BG_T may expose the first sub-substrate 200, and may be spaced apart at regular intervals in the second direction D2.

Unlike the shown example, at least a part of the buried insulating layer 201 may not be removed, while the back gate trench BG_T is being formed.

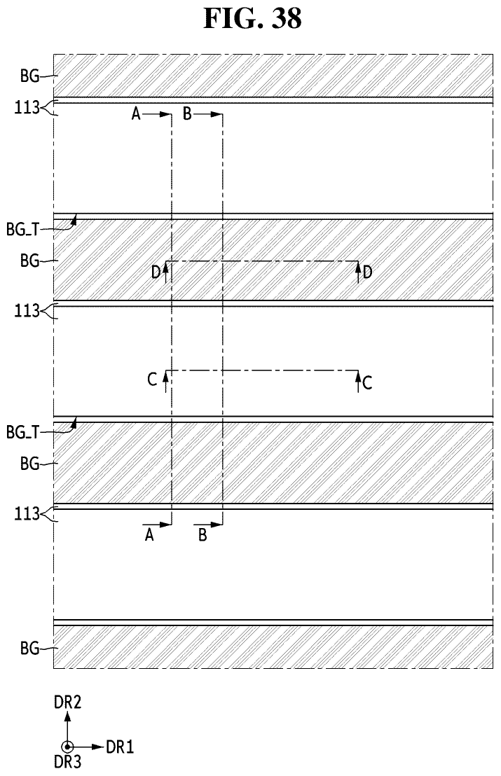

Referring to FIGS. 38 to 40, the back gate insulating films 113 and the back gate electrodes BG may be formed inside the back gate trench BG_T.

For example, the back gate insulating film 113 may be formed along the side wall and the bottom surface of the back gate trench BG_T and the upper surface of the mask pattern MP1. The back gate conductive film may be formed on the back gate insulating film 113. The back gate conductive film may fill the back gate trench BG_T. Subsequently, the back gate conductive film may be isotropically etched to form back gate electrodes BG extending in the first direction D1. The back gate electrodes BG may partially fill the back gate trench BG_T.

While the back gate electrode BG is being formed, a back gate metal oxide film BGMOX may be formed along the boundary between the back gate insulating film 113 and the back gate electrode BG. In addition, a part of the back gate electrode BG may be oxidized to form a back gate capping metal oxide film CBGMOX.

Meanwhile, according to some example embodiments, a gas phase doping (GPD) process or a plasma doping (PLAD) process may be performed before forming the back gate insulating film 113. The active layer 202 exposed by the back gate trench BG_T may be doped with impurities through the aforementioned process.

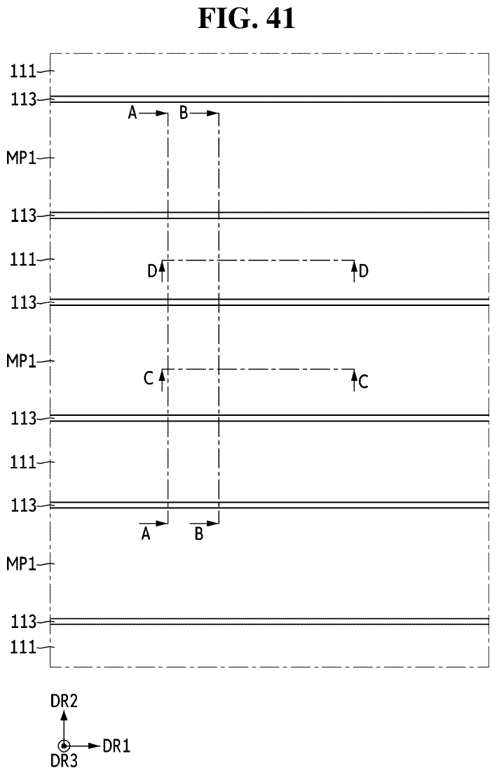

Referring to FIGS. 41 to 43, the back gate separation patterns 111 may be formed on the back gate electrode BG.

The back gate separation pattern 111 may be formed on the back gate capping metal oxide film CBGMOX. The back gate separation pattern 111 may fill the remainder of the back gate trench BG_T. When the back gate separation pattern 111 and the back gate insulating film 113 are made of or include the same material (for example, silicon oxide), the back gate insulating film 113 on the upper surface of the mask pattern MP1 may be removed, while the back gate separation pattern 111 is being formed.

Meanwhile, before forming the back gate separation patterns 111, the gas phase doping (GPD) process or the plasma doping (PLAD) process may be performed. Accordingly, the active layer 202 may be doped with impurities through the back gate trench BG_T in which the back gate electrode BG is formed.

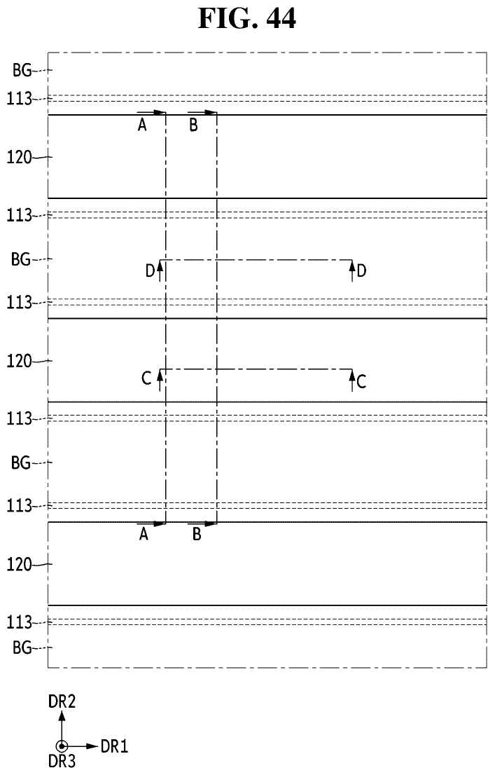

Referring to FIGS. 44 to 46, after forming the back gate separation patterns 111, the first upper mask film 12 may be removed.

The back gate separation patterns 111 may have shapes that protrude above the upper surface of the first lower mask film 11.

The spacer film 120 may then be formed along the upper face of the first lower mask film 11, the side walls of the back gate insulating films 113, and the upper surfaces of the back gate separation patterns 111. The spacer film 120 may be formed to have a uniform thickness. The widths of the active patterns of the vertical channel transistors may be determined depending on the deposited thickness of the spacer film 120.

The spacer film 120 may be made of or include an insulating material. The spacer film 120 may include, for example, silicon oxide, silicon oxynitride, silicon nitride, silicon carbide (SiC), silicon carbon nitride film (SiCN), and combinations thereof.

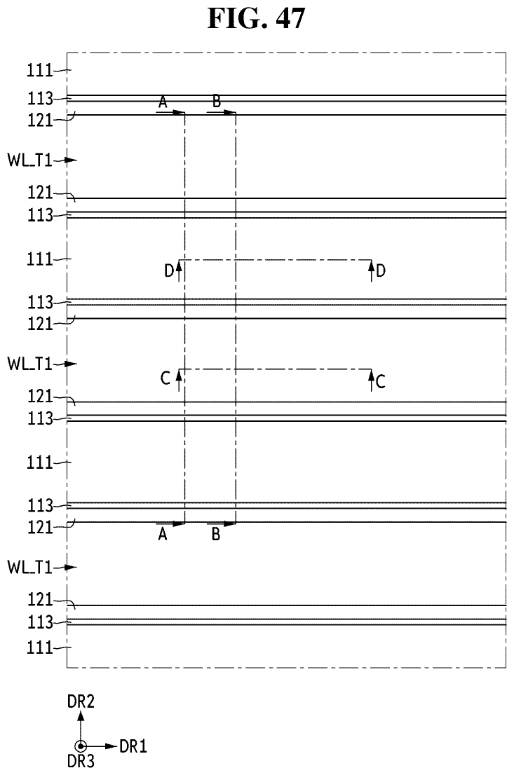

Referring to FIGS. 47 to 49, a pair of spacer patterns 121 may be formed on the side walls of the back gate insulating film 113, by performing an anisotropic etching process on the spacer film 120.

The anisotropic etching process may be performed on the active layer 202, by using the spacer pattern 121 as an etching mask. Accordingly, a pair of pre-active patterns PAP separated from each other may be formed on both sides of each back gate insulating film 113. As the pre-active patterns PAP are formed, the buried insulating layer 201 may be exposed.

The pre-active patterns PAP may extend in the first direction D1 alongside of the back gate electrode BG. While the pre-active patterns PAP are being formed, a word line trench WL_T1 may be formed between the pre-active patterns PAP adjacent to each other in the second direction D2.

Referring to FIGS. 47 to 52, a sacrificial film which fills the word line trench WL_T1 may be formed. The pattern mask may be formed on the sacrificial film. The pattern mask may have a line shape extending in the second direction D2. As another example, the pattern mask may have a line shape extending in the diagonal direction with respect to the first direction D1 and the second direction D2. The sacrificial film may be etched using the pattern mask as an etch mask to form sacrificial openings inside the sacrificial film.

By etching the pre-active patterns PAP exposed to the sacrificial openings, the first active pattern AP1 and the second active pattern AP2 may be formed on both sides of the back gate electrode BG. The first active patterns AP1 may be formed on the first side wall of the back gate electrode BG to be spaced apart from each other in the first direction D1. The second active patterns AP2 may be formed on the second side wall of the back gate electrode BG to be spaced apart from each other in the first direction D1. Because the first active pattern AP1 and the second active pattern AP2 are formed, the sacrificial openings may expose a part of the back gate insulating film 113.

The sacrificial film, the pattern mask, and the spacer pattern 121 may then be removed. The first lower mask film 11 may remain on the first active pattern AP1 and the second active pattern AP2. The buried insulating layer 201 may be exposed.

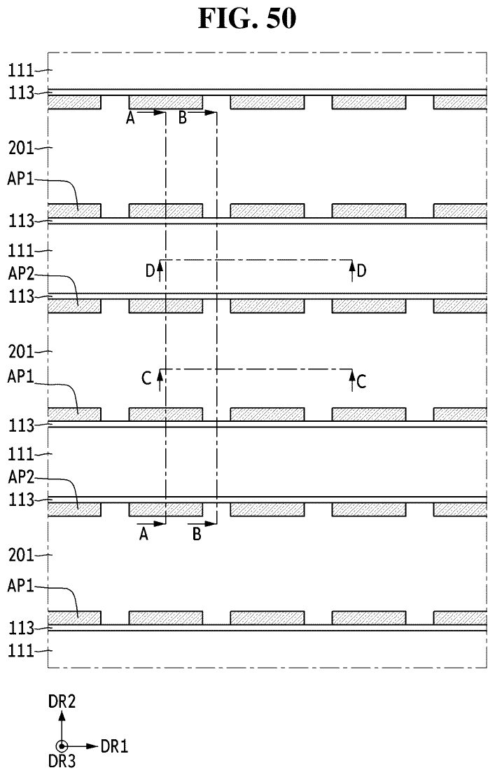

Referring to FIGS. 50 to 54, the gate shielding pattern 145 may be formed inside the word line trench WL_T1.

The gate shielding pattern 145 may fill a part of the word line trench WL_T1. The gate shielding pattern 145 may be formed on the buried insulating layer 201.

The first gate insulating film GOX1 may be formed along the side walls of the first active pattern AP1, the side walls of the second active pattern AP2, and the upper surface of the back gate separation pattern 111.

The first gate insulating film GOX1 may be formed using at least one of, but example embodiments are not limited to, physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Unlike the shown example, the gate shielding pattern 145 may not be formed before the first gate insulating pattern GOX1 is formed.

Next, an impurity film IM_L may be formed on the first gate insulating film GOX1. The impurity film IM_L may be formed along the profile of the first gate insulating film GOX1. The impurity film IM_L may be formed along the side wall of the first active pattern AP1, the side wall of the second active pattern AP2, and the upper surface of the back gate separation pattern 111.

The impurity film IM_L may include a first impurity element. The first impurity element may include at least one of niobium (Nb), tantalum (Ta), vanadium (V), zirconium (Zr), aluminum (Al), molybdenum (Mo), cobalt (Co), phosphorus (P), nitrogen (N), or arsenic (As).

As an example, the impurity film IM_L may be formed, using an atomic layer deposition (ALD) method. The impurity film IM_L may include metal oxide of a metal element among the first impurity elements. When the impurity film IM_L is formed by the atomic layer deposition (ALD) method, the impurity film IM_L may include at least one of niobium oxide, tantalum oxide, vanadium oxide, zirconium oxide, aluminum oxide, molybdenum oxide, or cobalt oxide.

As another example, the impurity film IM_L may be formed using a gas phase doping (GPD) process. Among the first impurity elements, phosphorus (P), nitrogen (N), and arsenic (As) may be difficult to deposit in the form of oxide. The impurity film IM_L including phosphorus (P), nitrogen (N), and arsenic (As), which are difficult to deposit in the form of oxide, may be formed using a gas phase doping (GPD) process. While the impurity film IM_L is being formed, the first impurity element may diffuse into the exposed first gate insulating film GOX1. Because the first impurity element is injected into the first gate insulating film GOX1 through a diffusion process, it is possible to reduce or prevent damage to the first gate insulating film GOX1 due to the injection of the first impurity element. Although the impurity film IM_L is shown to have the form of a deposited film, the embodiment is not limited thereto. As an example, the impurity film IM_L may have the form of a deposited film including the first impurity element. As another example, the impurity film IM_L may be a diffusion region of the first impurity element formed by diffusing the first impurity element into the first gate insulating film GOX1. That is, the impurity film IM_L may not have the form of a deposition film. As another example, the impurity film IM_L may be a combination of the form of a deposition film including the first impurity element and the diffusion region of the first impurity element formed by diffusing the first impurity element.

Next, a first pre-word line pattern P_WL may be formed on the impurity film IM_L. The first pre-word line pattern P_WL may fill the word line trench WL_T1. The first pre-word line pattern P_WL may be formed on the upper surface of the back gate separation pattern 111.

Unlike the shown example, the first pre-word line pattern P_WL may fill a part of the word line trench WL_T1.

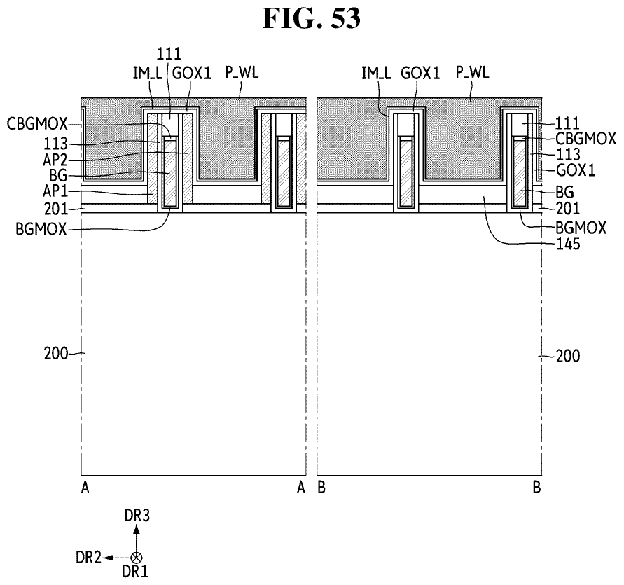

Referring to FIGS. 53 to 56, the first pre-word line pattern P_WL, the first gate insulating film GOX1, and the impurity film IM_L may be heat-treated through a heat treatment process 50.

A metal element included in the first pre-word line pattern P_WL may be oxidized through the heat treatment process 50 to form a first gate metal oxide film GMOX1 between the first gate insulating film GOX1 and the first pre-word line pattern P_WL. While the first gate metal oxide film GMOX1 is being formed, the first impurity element included in the impurity film IM_L may diffuse into the first gate metal oxide film GMOX1. The first gate metal oxide film GMOX1 includes a doped first impurity element.

Unlike the shown example, a part of the impurity film IM_L may remain after the heat treatment process 50 is performed. In this case, a part of the impurity film IM_L may be the second gate metal oxide film (GMOX2 of FIGS. 9 and 10).

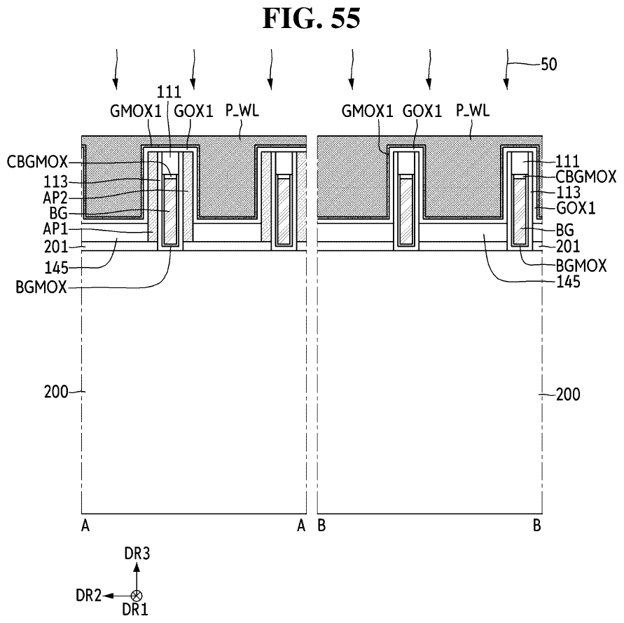

Referring to FIGS. 55 to 58, a part of the first pre-word line pattern P_WL may be removed to form a second pre-word line pattern P_WL1 inside the word line trench WL_T1.

The second pre-word line pattern P_WL1 may fill a part of the word line trench WL_T1. Also, a part of the second pre-word line pattern P_WL1 may be oxidized to form a first capping gate metal oxide film CGMOX1.

While the back gate electrode BG shown in FIGS. 38 to 40 is being formed, a back gate metal oxide film (BGMOX of FIGS. 11 and 12) doped with a second impurity element may be formed through the method explained using FIGS. 53 to 56.

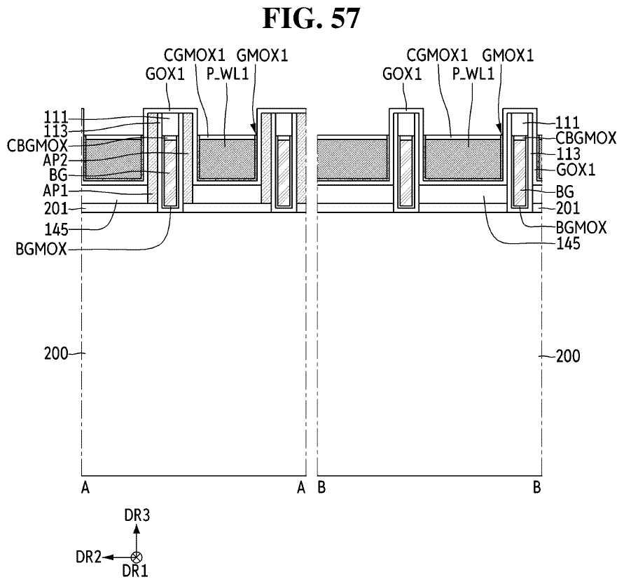

Referring to FIGS. 57 to 60, the second pre-word line pattern P_WL1 may be patterned to form the first word line WL1 and the second word line WL2.

The second pre-word line pattern P_WL1 may be formed, for example, by using an anisotropic etching process. Depending on how the second pre-word line pattern P_WL1 is patterned, the width of the first word line WL1 in the second direction DR2 may be the same as or different from the width of the second word line WL2 in the second direction DR2.

As an example, after forming the first and second word lines WL1 and WL2, a gas phase doping (GPD) process or a plasma doping (PLAD) process may be performed. As a result, the first and second active patterns AP1 and AP2 may be doped with impurities through the first gate insulating film GOX1 exposed by the first and second word lines WL1 and WL2.

Next, a gate separation pattern GSS may be formed on the first word line WL1 and the second word line WL2. For example, the upper surface of the gate separation pattern GSS may be disposed on the same plane as the upper face of the back gate capping pattern 115.

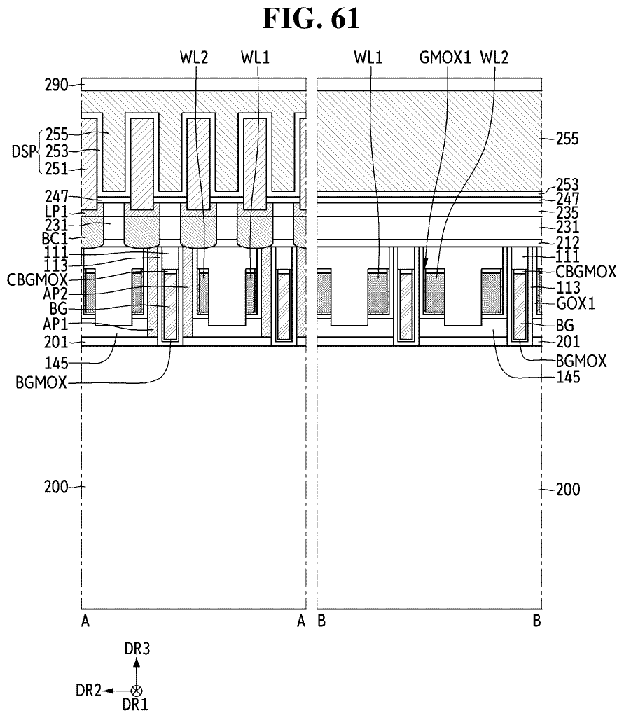

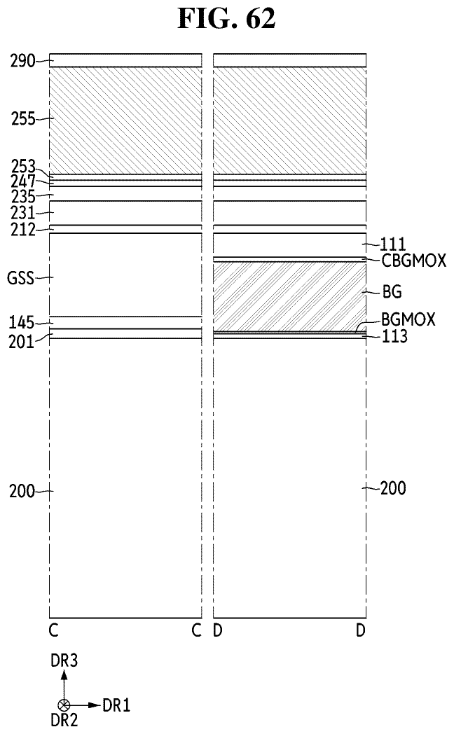

Referring to FIGS. 61 and 62, contact holes for exposing the first and second active patterns AP1 and AP2 may be formed inside the contact etching stop film 212 and the contact interlayer insulating film 231.

The first contact pattern BC1 may be formed inside the contact hole. The first contact patterns BC1 may be formed on the first active pattern AP1 and the second active pattern AP2. The first contact patterns BC1 may be connected to the first active pattern AP1 and the second active pattern AP2. Data storage patterns DSP may be formed on the first contact pattern BC1.

Next, a cell upper insulating film 290 may be formed on the data storage pattern DSP.

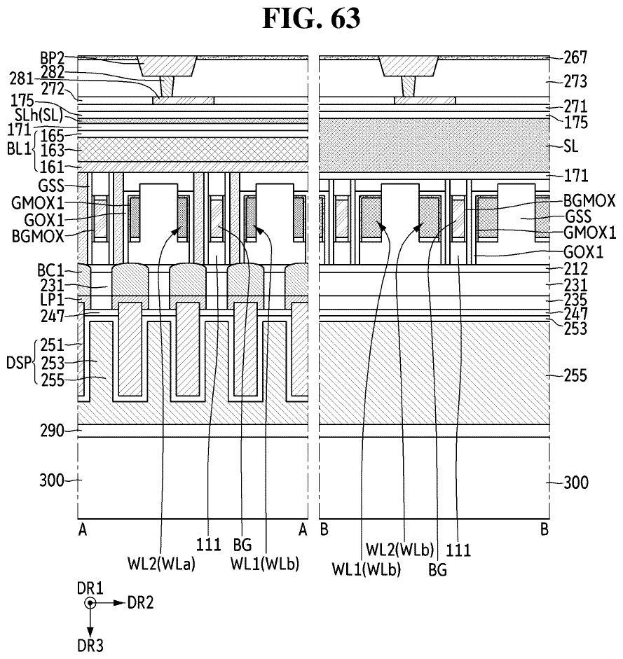

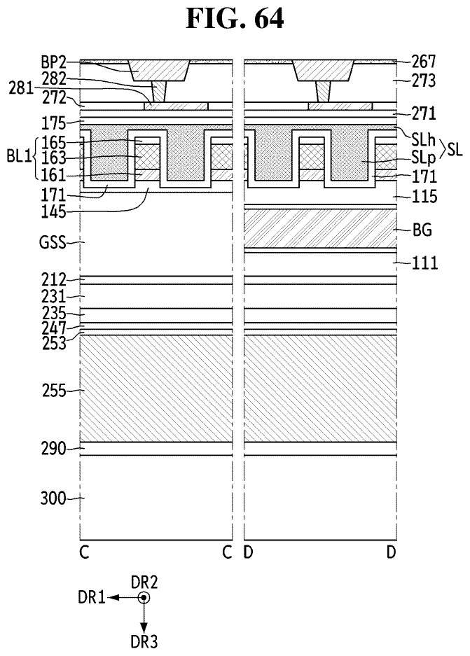

Referring to FIGS. 63 and 64, a first sub-substrate 200, on which back gate electrodes BG, word lines WL1 and WL2, active patterns AP1 and AP2 and data storage patterns DSP are formed, may be bonded to a second sub-substrate 300.

The back gate electrodes BG, the word lines WL1 and WL2, the active patterns AP1 and AP2, and the data storage patterns DSP may be disposed between the first sub-substrate 200 and the second sub-substrate 300.

Although not shown, the first sub-substrate 200 and the second sub-substrate 300 may be bonded using a bonding adhesive film.

As an example, the second sub-substrate 300 may be a semiconductor substrate. As another example, the second sub-substrate 300 may be an insulating substrate including an insulating material.

Then, after bonding the first sub-substrate 200 and the second sub-substrate 300, a back lapping process for removing the first sub-substrate 200 may be performed.

Removal of the first sub-substrate 200 may include sequentially performing a polishing process and a wet etching process to expose the buried insulating layer 201. The first sub-substrate 200 may be removed to expose a part of the back gate insulating film 113.

Next, the buried insulating layer 201 may be removed to expose the first active pattern AP1 and the second active pattern AP2. While the buried insulating layer 201 is being removed, a part of the back gate insulating film 113 may be removed. Accordingly, the back gate electrode BG may be exposed.

Next, an etch-back process may be performed to remove a part of the back gate electrode BG. A back gate capping pattern 115 may be formed on the recessed back gate electrode BG.

Next, a first bit line BL1 extending in the second direction DR2 may be formed on the first active pattern AP1 and the second active pattern AP2. A shielding conductive pattern SL may be formed on the first bit line BL1. A shielding insulating capping film 175 may be formed on the shielding conductive pattern SL.

Next, a first cell lower insulating film 271 may be formed on the shielding insulating capping film 175. A second cell lower insulating film 272 may be formed on the first cell lower insulating film 271. A cell connecting wiring 281 may be formed inside the second cell lower insulating film 272. The third cell lower insulating film 273 may be formed on the second cell lower insulating film 272. The upper pad plug 282 and the upper bonding pad BP2 may be formed inside the third cell lower insulating film 273.

Next, referring to FIGS. 18 and 19, the substrate 100, on which the peri-gate structure PG, the first peri-connecting structure 242a and 242b, the second peri-connecting structure 243a and 243b, the lower bonding pad BP1, and the lower pad plug 244 are formed, may be bonded to the second sub-substrate 300.

The second sub-substrate 300 and the substrate 100 may be bonded, using a bonding adhesive film 267. Unlike the shown example, the second sub-substrate 300 and the substrate 100 may be bonded without the bonding adhesive film 267.

Next, the second sub-substrate 300 may be removed.

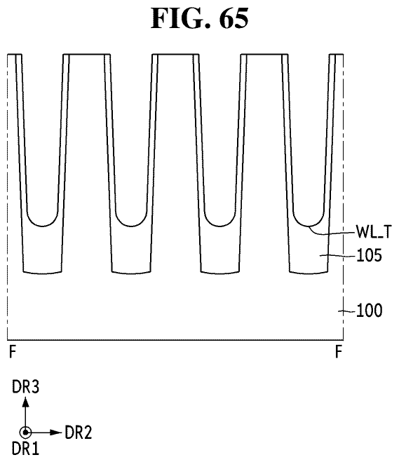

FIGS. 65 to 69 are intermediate stage diagrams for explaining a method for fabricating a semiconductor memory device according to some example embodiments.

Referring to FIG. 65, an element separation film 105 may be formed inside the substrate 100.

The element separation film 105 may define a cell active region (ACT of FIG. 28).

Next, a cell gate trench WL_T may be formed. The cell gate trench WL_T may be formed on the element separation film 105. Although not shown, the cell gate trench WL_T may be formed inside the substrate 100.

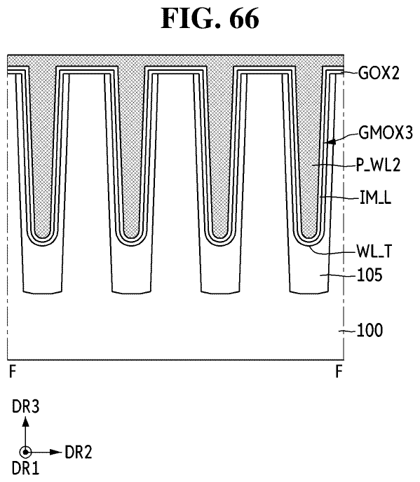

Referring to FIG. 66, a second gate insulating film GOX2 may be formed along a profile of the cell gate trench WL_T.

The second gate insulating film GOX2 may be formed along an upper face of the substrate 100.

The impurity film IM_L may be formed on the second gate insulating film GOX2. The impurity film IM_L may be formed along the profile of the second gate insulating film GOX2.

As an example, the impurity film IM_L including the first impurity element may be formed using an atomic layer deposition (ALD) method. As another example, the impurity film IM_L including the first impurity element may be formed using a gas phase doping (GPD) process.

Subsequently, a third pre-word line pattern P_WL2 may be formed on the impurity film IM_L. The third pre-word line pattern P_WL2 may fill the cell gate trench WL_T. The third pre-word line pattern P_WL2 may be formed on the upper surface of the substrate 100.

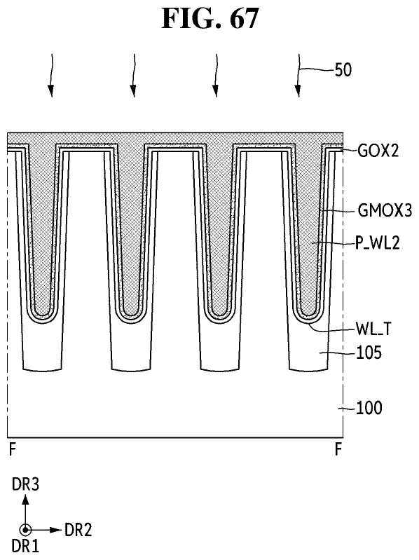

Referring to FIGS. 66 and 67, the third pre-word line pattern P_WL2, the second gate insulating film GOX2, and the impurity film IM_L may be heat-treated through the heat treatment process 50.

A third gate metal oxide film GMOX3 doped with a first impurity element may be formed on the second gate insulating film GOX2 through the heat treatment process 50. While the heat treatment process 50 is progressing, the first impurity element included in the impurity film IM_L may diffuse into the third gate metal oxide film GMOX3.

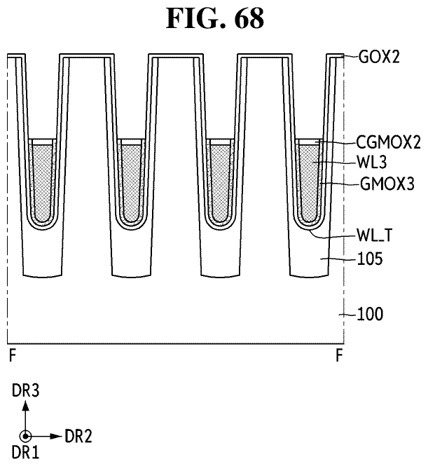

Referring to FIGS. 67 and 68, a part of the third pre-word line pattern P_WL2 may be removed to form a third word line WL3 inside the cell gate trench WL_T.

The third word line WL3 may fill a part of the cell gate trench WL_T. Also, a part of the third word line WL3 may be oxidized to form a second capping gate metal oxide film CGMOX2.

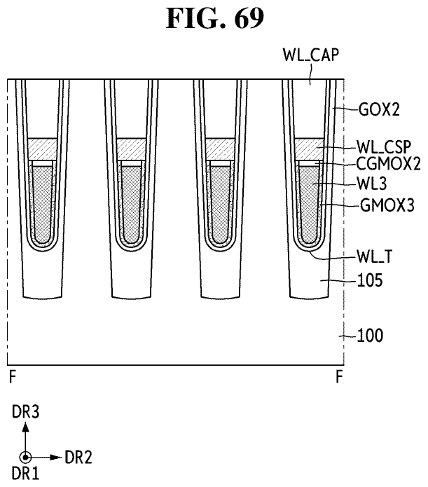

Referring to FIG. 69, a gate capping conductive film WL_CSP may be formed on the second capping gate metal oxide film CGMOX2.

Next, a gate capping film WL_CAP may be formed on the gate capping conductive film WL_CSP.

The gate capping film WL_CAP may be formed inside the cell gate trench WL_T. The gate capping film WL_CAP may fill the cell gate trench WL_T.

In concluding the detailed description, those skilled in the art will appreciate that many variations and modifications may be made to the disclosed example embodiments without substantially departing from the principles of the present disclosure. Therefore, the disclosed example embodiments of the disclosure are used in a generic and descriptive sense only and not for purposes of limitation.

What is claimed is:

1. A semiconductor memory device comprising:
a channel region;
a word line extending in a first direction;
a gate insulating film being between the channel region and the word line, the gate insulating film including silicon oxide;
a first gate metal oxide film being between the gate insulating film and the word line, the first gate metal oxide film including first metal oxide; and
a capping gate metal oxide film on an upper face of the word line, the capping gate metal oxide film including second metal oxide,
wherein the first gate metal oxide film includes a doped impurity element, and
a concentration of the doped impurity element in the first gate metal oxide film is greater than a concentration of the doped impurity element in the capping gate metal oxide film.

2. The semiconductor memory device of claim 1, wherein a thickness of the capping gate metal oxide film is greater than a thickness of the first gate metal oxide film.

3. The semiconductor memory device of claim 1, wherein
the word line includes a metal element, and
the first gate metal oxide film and the capping gate metal oxide film include oxide of the metal element.

4. The semiconductor memory device of claim 1, wherein the capping gate metal oxide film does not include the doped impurity element.

5. The semiconductor memory device of claim 1, wherein
the concentration of the doped impurity element in the capping gate metal oxide film decreases, the further the capping gate metal is away from the first gate metal oxide film in a second direction, the second direction is perpendicular to the first direction.

6. The semiconductor memory device of claim 1, wherein the doped impurity element includes at least one of niobium (Nb), tantalum (Ta), vanadium (V), zirconium (Zr), aluminum (Al), molybdenum (Mo), cobalt (Co), phosphorus (P), nitrogen (N), or arsenic (As).

7. The semiconductor memory device of claim 1, wherein
the first gate metal oxide film includes a first interface and a second interface, the first interface facing the gate insulating film, the second interface facing the word line,
the concentration of the doped impurity element at the first interface of the first gate metal oxide film is a first impurity concentration, and
the concentration of the doped impurity element at the second interface of the first gate metal oxide film is a second impurity concentration, the second impurity concentration being smaller than the first impurity concentration.

8. The semiconductor memory device of claim 1, wherein the gate insulating film does not include the doped impurity element.

9. The semiconductor memory device of claim 1, further comprising:
a second gate metal oxide film between the gate insulating film and the first gate metal oxide film, and
the second gate metal oxide film includes oxide of the doped impurity element.

10. The semiconductor memory device of claim 1, wherein
the channel region is a silicon active pattern extending in the first direction,
the silicon active pattern includes a first side wall and a second side wall that are opposite to each other in a second direction, the second direction being perpendicular to the first direction, and
the word line, the gate insulating film and the first gate metal oxide film are on the first side wall of the silicon active pattern.

11. The semiconductor memory device of claim 1, wherein
the channel region is included in a substrate,
the substrate includes a cell gate trench, and
the word line, gate insulating film, and the first gate metal oxide film are inside the cell gate trench.

12. The semiconductor memory device of claim 1, further comprising:
a bit line and a data storage pattern connected to the channel region.

13. A semiconductor memory device comprising:
a bit line extending in a first direction on a substrate;
an active pattern on the bit line, the active pattern including a first side wall and a second side wall that are opposite to each other in the first direction, the active pattern including a first surface and a second surface that are opposite to each other in a vertical direction, the first surface of the active pattern being connected to the bit line;
a word line on the first side wall of the active pattern, the word line extending in a second direction, the word line including a first surface and a second surface that are opposite to each other in the vertical direction;
a gate insulating film extending along the first side wall of the active pattern, the gate insulating film being in contact with the active pattern, the gate insulating film including silicon oxide;
a gate metal oxide film between the gate insulating film and the word line, the gate metal oxide film including first metal oxide that is oxide of a metal element included in the word line;
a capping gate metal oxide film on the first surface of the word line, the capping gate metal oxide film including the first metal oxide;
a back gate electrode on the second side wall of the active pattern, the back gate electrode extending in the second direction; and
a data storage pattern on the active pattern, the data storage pattern connected to the second surface of the active pattern,
wherein the gate metal oxide film includes a doped first impurity element, and
a thickness of the capping gate metal oxide film is greater than a thickness of the gate metal oxide film.

14. The semiconductor memory device of claim 13, wherein the capping gate metal oxide film does not include the doped first impurity element.

15. The semiconductor memory device of claim 13, wherein
the capping gate metal oxide film includes the doped first impurity element, and
a concentration of the first impurity element in the gate metal oxide film is greater than a concentration of the first impurity element in the capping gate metal oxide film.

16. The semiconductor memory device of claim 13, further comprising:
a back gate insulating film extending along the second side wall of the active pattern, the back gate insulating film being in contact with the active pattern, the back gate insulating film including silicon oxide; and
a back gate metal oxide film between the back gate insulating film and the back gate electrode, the back gate metal oxide film including a second metal oxide,
wherein the back gate metal oxide film includes oxide of a metal element included in the back gate electrode,
the back gate metal oxide film includes a second impurity element, and
the second impurity element includes at least one of niobium (Nb), tantalum (Ta), vanadium (V), zirconium (Zr), aluminum (Al), molybdenum (Mo), cobalt (Co), phosphorus (P), nitrogen (N), or arsenic (As).

17. The semiconductor memory device of claim 13, wherein the doped first impurity element includes at least one of niobium (Nb), tantalum (Ta), vanadium (V), zirconium (Zr), aluminum (Al), molybdenum (Mo), cobalt (Co), phosphorus (P), nitrogen (N), or arsenic (As).

18. A semiconductor memory device comprising:
a peri-gate structure on a substrate;
a bit line extending in a first direction on the peri-gate structure;
a shielding conductive pattern on the peri-gate structure, the shielding conductive pattern including a plurality of shielding conductive line patterns extending in the first direction to be adjacent to the bit line;
a first word line on the bit line and the shielding conductive pattern, the first word line extending in a second direction, the first word line including a first surface and a second surface that are opposite to each other in a vertical direction;
a second word line on the bit line and the shielding conductive pattern, the second word line extending in the second direction, the second word line being spaced apart from the first word line in the first direction;
a back gate electrode between the first word line and the second word line, the back gate electrode extending in the second direction;
a first active pattern on the bit line, the first active pattern being between the first word line and the back gate electrode;
a second active pattern on the bit line, the second active pattern being between the second word line and the back gate electrode;
a first gate metal oxide film between the first word line and the first active pattern, the first gate metal oxide film including first metal oxide;
a second gate metal oxide film between the second word line and the second active pattern, the second gate metal oxide film including the first metal oxide;
a back gate metal oxide film being between the back gate electrode and the first active pattern and being between the back gate electrode and the second active pattern, and the back gate metal oxide film including second metal oxide; and
a data storage pattern connected to a respective one of the first active pattern and the second active pattern,
wherein each of the first gate metal oxide film and the second gate metal oxide film includes a first impurity element,
the first word line and the second word line include a metal element,
the first metal oxide is oxide of the metal element, and
the first impurity element includes at least one of niobium (Nb), tantalum (Ta), vanadium (V), zirconium (Zr), aluminum (Al), molybdenum (Mo), cobalt (Co), phosphorus (P), nitrogen (N), or arsenic (As).

19. The semiconductor memory device of claim 18, further comprising:
a capping gate metal oxide film on the first surface of the first word line, the capping gate metal oxide film including the first metal oxide,
wherein a thickness of the capping gate metal oxide film is greater than a thickness of the first gate metal oxide film.

20. The semiconductor memory device of claim 18, wherein
the back gate metal oxide film includes a second impurity element, and
the second impurity element includes at least one of niobium (Nb), tantalum (Ta), vanadium (V), zirconium (Zr), aluminum (Al), molybdenum (Mo), cobalt (Co), phosphorus (P), nitrogen (N), or arsenic (As).
